(19) United States
(12) Patent Application Publication
(10) Pub. No.: US 2026/0237354 A1
(43) Pub. Date: Aug. 13, 2026

(54) SHIFT REGISTER, GATE DRIVING CIRCUIT, AND DRIVING METHOD FOR SHIFT REGISTER

(71) Applicants: Chengdu BOE Optoelectronics Technology Co., Ltd., Chengdu, Sichuan (CN); BOE Technology Group Co., Ltd., Beijing (CN)

(72) Inventors: Mengqi WANG, Beijing (CN); Ziyang YU, Beijing (CN); Jianpeng WU, Beijing (CN); Tiaomei ZHANG, Beijing (CN); Zhiliang JIANG, Beijing (CN); Ming HU, Beijing (CN); Haijun QIU, Beijing (CN); Xing YAO, Beijing (CN)

(21) Appl. No.: 19/149,079

(22) PCT Filed: Jun. 12, 2024
(86) PCT No.: PCT/CN2024/098627

§ 371 Date: Jul. 17, 2025

(30) Foreign Application Priority Data
Jul. 11, 2023 (CN) 202310849051.0

(51) Int. Cl. G09G 3/3266; G11C 19/28

(52) U.S. Cl. CPC G09G 3/3266; G11C 19/28; G09G 2300/0408; G09G 2310/0286; G09G 2330/021

(57) ABSTRACT

A shift register, a gate driving circuit, and a driving method for a shift register. The shift register comprises: a cascade output sub-circuit, an output control sub-circuit, and a scanning output sub-circuit, wherein the cascade output sub-circuit is configured to provide a signal of a first power supply end or a second power supply end to a cascade output end under the control of signals of an input end, a first clock signal end, a second clock signal end, a first node, a second node and a third node; the output control sub-circuit is configured to provide the signal of the first node to a fourth node and the signal of the second node to a fifth node under the control of signals of the first node, the third node and a first control signal end to a third control signal end.

### CROSS-REFERENCE TO RELATED APPLICATIONS

This application is a U.S. National Phase Entry of International Application PCT/CN2024/098627 having an international filing date of Jun. 12, 2024, which claims priority to a Chinese Patent Application No. 202310849051.0, filed to the CNIPA on Jul. 11, 2023 and entitled “Shift Register, Gate Driving Circuit, and Driving Method for Shift Register”, the contents of the above-identified applications should be construed as being incorporated herein by reference.

### TECHNICAL FIELD

The present disclosure relates to, but is not limited to, display technologies, and in particular to a shift register, a gate driving circuit, and a method for driving the shift register.

### BACKGROUND

An organic light emitting diode (OLED) and a quantum dot light emitting diode (QLED) are active light emitting display devices and have advantages such as self-illumination, wide viewing angle, high contrast ratio, low power consumption, very high reaction speed, lightness and thinness, flexibility, and low cost, etc. With constant development of display technologies, a flexible display apparatus (Flexible Display) in which an OLED or a QLED is used as a light emitting device and signal control is performed through a thin film transistor (TFT) has become a mainstream product in the field of display at present.

### SUMMARY

The following is a summary of subject matter described in the present disclosure in detail. This summary is not intended to limit the protection scope of claims.

According to a first aspect, an embodiment of the present disclosure provides a shift register including: a cascade output sub-circuit, an output control sub-circuit, and a scan output sub-circuit.

The cascade output sub-circuit is electrically connected to an input terminal, a first clock signal terminal, a second clock signal terminal, a first power supply terminal, a second power supply terminal, a cascade output terminal, a first node, a second node, and a third node, respectively, and is configured to provide a signal of the first power supply terminal or the second power supply terminal to the cascade output terminal under control of signals of the input terminal, the first clock signal terminal, the second clock signal terminal, the first node, the second node, and the third node.

The output control sub-circuit is electrically connected to a first control signal terminal to a third control signal terminal, the first node, the second node, the third node, a fourth node, and a fifth node, respectively, and is configured to provide a signal of the first node to the fourth node and to provide a signal of the second node to the fifth node under control of signals of the first node, the third node, and the first control signal terminal to the third control signal terminal.

The scan output sub-circuit is electrically connected to the fourth node, the fifth node, a scan signal output terminal, the first power supply terminal, and the second power supply terminal, respectively, and is configured to output the signal of the first power supply terminal or the second power supply terminal to the scan signal output terminal under control of signals of the fourth node and the fifth node.

In some possible implementation modes, the output control sub-circuit includes: a first control sub-circuit, a second control sub-circuit, and a third control sub-circuit.

The first control sub-circuit is electrically connected to the first node, the third node, a sixth node, and the first control signal terminal to the third control signal terminal respectively, and is configured to provide a signal of the second control signal terminal or the third control signal terminal to the sixth node under control of the signals of the first node, the third node, and the first control signal terminal.

The second control sub-circuit is electrically connected to the first node, the fourth node, and the sixth node respectively, and is configured to provide the signal of the first node to the fourth node under control of a signal of the sixth node.

The third control sub-circuit is electrically connected to the second node, the fifth node and the sixth node respectively, and is configured to provide the signal of the second node to the fifth node under control of the signal of the sixth node.

In some possible implementation modes, the first control sub-circuit includes: a first transistor, a second transistor, a third transistor, and a fourth transistor.

A control electrode of the first transistor is electrically connected to the first control signal terminal, a first electrode of the first transistor is electrically connected to a second electrode of the second transistor, and a second electrode of the first transistor is electrically connected to the third control signal terminal.

A control electrode of the second transistor is electrically connected to the third node, and a first electrode of the second transistor is electrically connected to the sixth node.

A control electrode of the third transistor is electrically connected to the first control signal terminal, a first electrode of the third transistor is electrically connected to the second control signal terminal, and a second electrode of the third transistor is electrically connected to a first electrode of the fourth transistor.

A control electrode of the fourth transistor is electrically connected to the first node, and a second electrode of the fourth transistor is electrically connected to the sixth node.

In some possible implementation modes, the second control sub-circuit includes a fifth transistor.

A control electrode of the fifth transistor is electrically connected to the sixth node, a first electrode of the fifth transistor is electrically connected to the first node, and a second electrode of the fifth transistor is electrically connected to the fourth node.

In some possible implementation modes, the third control sub-circuit includes a sixth transistor.

A control electrode of the sixth transistor is electrically connected to the sixth node, a first electrode of the sixth transistor is electrically connected to the second node, and a second electrode of the sixth transistor is electrically connected to the fifth node.

In some possible implementation modes, the output control sub-circuit further includes: a storage sub-circuit.

The storage sub-circuit is electrically connected to the fourth node and the sixth node respectively, and is configured to store a voltage difference between signals of the sixth node and the fourth node.

In some possible implementation modes, the storage sub-circuit includes a first capacitor including a first plate and a second plate.

The first plate of the first capacitor is electrically connected to the sixth node, and the second plate of the first capacitor is electrically connected to the fourth node.

In some possible implementation modes, the scan output sub-circuit includes a seventh transistor, and an eighth transistor.

A control electrode of the seventh transistor is electrically connected to the fourth node, a first electrode of the seventh transistor is electrically connected to the first power supply terminal, and a second electrode of the seventh transistor is electrically connected to the scan signal output terminal.

A control electrode of the eighth transistor is electrically connected to the fifth node, a first electrode of the eighth transistor is electrically connected to the scan signal output terminal, and a second electrode of the eighth transistor is electrically connected to the second power supply terminal.

In some possible implementation modes, the scan output sub-circuit further includes: a second capacitor including a first plate and a second plate.

The first plate of the second capacitor is electrically connected to the fourth node, and the second plate of the second capacitor is electrically connected to the first power supply terminal.

In some possible implementation modes, the cascade output sub-circuit includes: a ninth transistor to a twenty-fifth transistor, and a third capacitor to a sixth capacitor.

A control electrode of the ninth transistor is electrically connected to the first node, a first electrode of the ninth transistor is electrically connected to the first power supply terminal, and a second electrode of the ninth transistor is electrically connected to the cascade output terminal.

A control electrode of the tenth transistor is electrically connected to the third node, a first electrode of the tenth transistor is electrically connected to the second power supply terminal, and a second electrode of the tenth transistor is electrically connected to the cascade output terminal.

A control electrode of the eleventh transistor is electrically connected to the second power supply terminal, a first electrode of the eleventh transistor is electrically connected to a seventh node, and a second electrode of the eleventh transistor is electrically connected to a ninth node.

A control electrode of the twelfth transistor is electrically connected to the second power supply terminal, a first electrode of the twelfth transistor is electrically connected to the second node, and a second electrode of the twelfth transistor is electrically connected to the third node.

A control electrode of the thirteenth transistor is electrically connected to a third power supply terminal, a first electrode of the thirteenth transistor is electrically connected to the first power supply terminal, and a second electrode of the thirteenth transistor is electrically connected to the second node.

A control electrode of the fourteenth transistor is electrically connected to the first clock signal terminal, a first electrode of the fourteenth transistor is electrically connected to the input terminal, and a second electrode of the fourteenth transistor is electrically connected to an eighth node.

A control electrode of the fifteenth transistor is electrically connected to the second power supply terminal, a first electrode of the fifteenth transistor is electrically connected to the eighth node, and a second electrode of the fifteenth transistor is electrically connected to a twelfth node.

A control electrode of the sixteenth transistor is electrically connected to the twelfth node, a first electrode of the sixteenth transistor is electrically connected to the third node, and a second electrode of the sixteenth transistor is electrically connected to the twelfth node.

A control electrode of the seventeenth transistor is electrically connected to the first clock signal terminal, a first electrode of the seventeenth transistor is electrically connected to the input terminal, and a second electrode of the seventeenth transistor is electrically connected to the second node.

A control electrode of the eighteenth transistor is electrically connected to the second node, a first electrode of the eighteenth transistor is electrically connected to the first clock signal terminal, and a second electrode of the eighteenth transistor is electrically connected to the seventh node.

A control electrode of the nineteenth transistor is electrically connected to the first clock signal terminal, a first electrode of the nineteenth transistor is electrically connected to the second power supply terminal, and a second electrode of the nineteenth transistor is electrically connected to the seventh node.

A control electrode of the twentieth transistor is electrically connected to the second node, a first electrode of the twentieth transistor is electrically connected to the second clock signal terminal, and a second electrode of the twentieth transistor is electrically connected to an eleventh node.

A control electrode of the twenty-first transistor is electrically connected to the seventh node, a first electrode of the twenty-first transistor is electrically connected to the first power supply terminal, and a second electrode of the twenty-first transistor is electrically connected to the eleventh node.

A control electrode of the twenty-second transistor is electrically connected to the ninth node, a first electrode of the twenty-second transistor is electrically connected to the second clock signal terminal, and a second electrode of the twenty-second transistor is electrically connected to a tenth node.

A control electrode of the twenty-third transistor is electrically connected to the second clock signal terminal, a first electrode of the twenty-third transistor is electrically connected to the tenth node, and a second electrode of the twenty-third transistor is electrically connected to the first node.

A control electrode of the twenty-fourth transistor is electrically connected to the second node, a first electrode of the twenty-fourth transistor is electrically connected to the first power supply terminal, and a second electrode of the twenty-fourth transistor is electrically connected to the first node.

A control electrode of the twenty-fifth transistor is electrically connected to the twelfth node, a first electrode of the twenty-fifth transistor is electrically connected to the twelfth node, and a second electrode of the twenty-fifth transistor is electrically connected to the fifth node.

The third capacitor includes a first plate and a second plate, the first plate of the third capacitor is electrically connected to the third node, and the second plate of the third capacitor is electrically connected to the eleventh node.

The fourth capacitor includes a first plate and a second plate, the first plate of the fourth capacitor is electrically connected to the second power supply terminal, and the second plate of the fourth capacitor is electrically connected to the cascade output terminal.

The fifth capacitor includes a first plate and a second plate, the first plate of the fifth capacitor is electrically connected to the ninth node, and the second plate of the fifth capacitor is electrically connected to the tenth node.

The sixth capacitor includes a first plate and a second plate, the first plate of the sixth capacitor is electrically connected to the first node, and the second plate of the sixth capacitor is electrically connected to the first power supply terminal.

In some possible implementation modes, the cascade output sub-circuit includes: a ninth transistor to a twenty-fifth transistor, a third capacitor to a sixth capacitor, the output control sub-circuit includes: a first transistor to a sixth transistor and a first capacitor, and the scan output sub-circuit includes: a seventh transistor, an eighth transistor, and a second capacitor.

A control electrode of the first transistor is electrically connected to the first control signal terminal, a first electrode of the first transistor is electrically connected to a second electrode of the second transistor, and a second electrode of the first transistor is electrically connected to the third control signal terminal.

A control electrode of the second transistor is electrically connected to the third node, and a first electrode of the second transistor is electrically connected to a sixth node.

A control electrode of the third transistor is electrically connected to the first control signal terminal, a first electrode of the third transistor is electrically connected to the second control signal terminal, and a second electrode of the third transistor is electrically connected to a first electrode of the fourth transistor.

A control electrode of the fourth transistor is electrically connected to the first node, and a second electrode of the fourth transistor is electrically connected to the sixth node.

A control electrode of the fifth transistor is electrically connected to the sixth node, a first electrode of the fifth transistor is electrically connected to the first node, and a second electrode of the fifth transistor is electrically connected to the fourth node.

A control electrode of the sixth transistor is electrically connected to the sixth node, a first electrode of the sixth transistor is electrically connected to the second node, and a second electrode of the sixth transistor is electrically connected to the fifth node.

A control electrode of the seventh transistor is electrically connected to the fourth node, a first electrode of the seventh transistor is electrically connected to the first power supply terminal, and a second electrode of the seventh transistor is electrically connected to the scan signal output terminal.

A control electrode of the eighth transistor is electrically connected to the fifth node, a first electrode of the eighth transistor is electrically connected to the scan signal output terminal, and a second electrode of the eighth transistor is electrically connected to the second power supply terminal.

A control electrode of the ninth transistor is electrically connected to the first node, a first electrode of the ninth transistor is electrically connected to the first power supply terminal, and a second electrode of the ninth transistor is electrically connected to the cascade output terminal.

A control electrode of the tenth transistor is electrically connected to the third node, a first electrode of the tenth transistor is electrically connected to the second power supply terminal, and a second electrode of the tenth transistor is electrically connected to the cascade output terminal.

A control electrode of the eleventh transistor is electrically connected to the second power supply terminal, a first electrode of the eleventh transistor is electrically connected to a seventh node, and a second electrode of the eleventh transistor is electrically connected to a ninth node.

A control electrode of the twelfth transistor is electrically connected to the second power supply terminal, a first electrode of the twelfth transistor is electrically connected to the second node, and a second electrode of the twelfth transistor is electrically connected to the third node.

A control electrode of the thirteenth transistor is electrically connected to a third power supply terminal, a first electrode of the thirteenth transistor is electrically connected to the first power supply terminal, and a second electrode of the thirteenth transistor is electrically connected to the second node.

A control electrode of the fourteenth transistor is electrically connected to the first clock signal terminal, a first electrode of the fourteenth transistor is electrically connected to the input terminal, and a second electrode of the fourteenth transistor is electrically connected to an eighth node.

A control electrode of the fifteenth transistor is electrically connected to the second power supply terminal, a first electrode of the fifteenth transistor is electrically connected to the eighth node, and a second electrode of the fifteenth transistor is electrically connected to a twelfth node.

A control electrode of the sixteenth transistor is electrically connected to the twelfth node, a first electrode of the sixteenth transistor is electrically connected to the third node, and a second electrode of the sixteenth transistor is electrically connected to the twelfth node.

A control electrode of the seventeenth transistor is electrically connected to the first clock signal terminal, a first electrode of the seventeenth transistor is electrically connected to the input terminal, and a second electrode of the seventeenth transistor is electrically connected to the second node.

A control electrode of the eighteenth transistor is electrically connected to the second node, a first electrode of the eighteenth transistor is electrically connected to the first clock signal terminal, and a second electrode of the eighteenth transistor is electrically connected to the seventh node.

A control electrode of the nineteenth transistor is electrically connected to the first clock signal terminal, a first electrode of the nineteenth transistor is electrically connected to the second power supply terminal, and a second electrode of the nineteenth transistor is electrically connected to the seventh node.

A control electrode of the twentieth transistor is electrically connected to the second node, a first electrode of the twentieth transistor is electrically connected to the second clock signal terminal, and a second electrode of the twentieth transistor is electrically connected to an eleventh node.

A control electrode of the twenty-first transistor is electrically connected to the seventh node, a first electrode of the twenty-first transistor is electrically connected to the first power supply terminal, and a second electrode of the twenty-first transistor is electrically connected to the eleventh node.

A control electrode of the twenty-second transistor is electrically connected to the ninth node, a first electrode of the twenty-second transistor is electrically connected to the second clock signal terminal, and a second electrode of the twenty-second transistor is electrically connected to a tenth node.

A control electrode of the twenty-third transistor is electrically connected to the second clock signal terminal, a first electrode of the twenty-third transistor is electrically connected to the tenth node, and a second electrode of the twenty-third transistor is electrically connected to the first node.

A control electrode of the twenty-fourth transistor is electrically connected to the second node, a first electrode of the twenty-fourth transistor is electrically connected to the first power supply terminal, and a second electrode of the twenty-fourth transistor is electrically connected to the first node.

A control electrode of the twenty-fifth transistor is electrically connected to the twelfth node, a first electrode of the twenty-fifth transistor is electrically connected to the twelfth node, and a second electrode of the twenty-fifth transistor is electrically connected to the fifth node.

The first capacitor includes a first plate and a second plate, the first plate of the first capacitor is electrically connected to the sixth node, and the second plate of the first capacitor is electrically connected to the fourth node.

The second capacitor includes a first plate and a second plate, the first plate of the second capacitor is electrically connected to the fourth node, and the second plate of the second capacitor is electrically connected to the first power supply terminal.

The third capacitor includes a first plate and a second plate, the first plate of the third capacitor is electrically connected to the third node, and the second plate of the third capacitor is electrically connected to the eleventh node.

The fourth capacitor includes a first plate and a second plate, the first plate of the fourth capacitor is electrically connected to the second power supply terminal, and the second plate of the fourth capacitor is electrically connected to the cascade output terminal.

The fifth capacitor includes a first plate and a second plate, the first plate of the fifth capacitor is electrically connected to the ninth node, and the second plate of the fifth capacitor is electrically connected to the tenth node.

The sixth capacitor includes a first plate and a second plate, the first plate of the sixth capacitor is electrically connected to the first node, and the second plate of the sixth capacitor is electrically connected to the first power supply terminal.

In some possible implementation modes, the shift register is disposed on a display substrate including: a plurality of scan signal lines, a working process of the display substrate including: display stages and blank stages between display stages; the display substrate includes: a plurality of display regions, and refresh frequencies of different display regions include a first refresh frequency and a second refresh frequency, and the first refresh frequency is greater than the second refresh frequency.

In a state in which the working process of the display substrate is in a blank stage, when a signal of the first control signal terminal is a low-level signal, signals of the second control signal terminal and the third control signal terminal are low-level signals.

In a state in which the working process of the display substrate is in a display stage and the shift register is connected to a scan signal line located in a display region at the first refresh frequency, when the signal of the first control signal terminal is a low-level signal, signals of the second control signal terminal and the third control signal terminal are low-level signals.

In a state in which the working process of the display substrate is in a display stage, the shift register is connected to a scan signal line located in a display region at the second refresh frequency, and the cascade output terminal of the shift register outputs a low-level signal, when the signal of the first control signal terminal is a low-level signal, a signal of the second control signal terminal is a high-level signal, and a signal of the third control signal terminal is a low-level signal.

In a state in which the working process of the display substrate is in a display stage, the shift register is connected to a scan signal line located in a display region at the second refresh frequency, and the cascade output terminal of the shift register outputs a high-level signal, when the signal of the first control signal terminal is a low-level signal, the signal of the second control signal terminal is a high-level signal, and the signal of the third control signal terminal is a low-level signal.

In a state in which the working process of the display substrate is in a display stage, the shift register is connected to a scan signal line located in a display region at the second refresh frequency, and the cascade output terminal of the shift register outputs a low-level signal, when the signal of the first control signal terminal is a low-level signal, the signal of the second control signal terminal is a high-level signal, and the signal of the third control signal terminal is a low-level signal.

A duration during which the signal of the first control signal terminal is a low-level signal is less than a duration during which either of the signal of the second control signal terminal and the signal of the third control signal terminal is a low-level signal.

According to a second aspect, an embodiment of the present disclosure provides a gate driving circuit, including a plurality of cascaded shift registers according to any one of the first aspect.

A cascade output terminal of an i-th stage of shift register is electrically connected to a input terminal of an (i+1)-th stage of shift register, 1≤i≤M−1, and M is a total number of stages of the shift registers.

According to a third aspect, an embodiment of the present disclosure provides a method for driving a shift register, configured to drive the shift register according to any one of the first aspect, wherein the method includes:
providing, by the cascade output sub-circuit, a signal of the first power supply terminal or the second power supply terminal to the cascade output terminal under control of signals of the input terminal, the first clock signal terminal, the second clock signal terminal, the first node, the second node and the third node;
providing, by the output control sub-circuit, a signal of the first node to the fourth node and a signal of the second node to the fifth node under control of signals of the first node, the third node and the first control signal terminal to the third control signal terminal; and
outputting, by the scan output sub-circuit, a signal of the first power supply terminal or the second power supply terminal to the scan signal output terminal under control of signals of the fourth node and the fifth node.

Other aspects of the present disclosure may be comprehended after the drawings and the detailed descriptions are read and understood.

### BRIEF DESCRIPTION OF DRAWINGS

Accompanying drawings are used to provide an understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1A is a schematic diagram of a structure of a shift register according to an embodiment of the present disclosure.

FIG. 1B is a schematic diagram of a structure of a shift register according to an embodiment of the present disclosure.

FIG. 2 is an equivalent circuit diagram of an output control sub-circuit according to an exemplary embodiment.

FIG. 3 is an equivalent circuit diagram of a first control sub-circuit according to an exemplary example.

FIG. 4 is an equivalent circuit diagram of a second control sub-circuit according to an exemplary example.

FIG. 5 is an equivalent circuit diagram of a third control sub-circuit according to an exemplary embodiment.

FIG. 6 is an equivalent circuit diagram of an output control sub-circuit according to an exemplary embodiment.

FIG. 7 is an equivalent circuit diagram of a storage sub-circuit according to an exemplary embodiment.

FIG. 8 is an equivalent circuit diagram of a scan output sub-circuit according to an exemplary embodiment.

FIG. 9 is an equivalent circuit diagram of a scan output sub-circuit according to an exemplary embodiment.

FIG. 10 is an equivalent circuit diagram of a cascade output sub-circuit according to an exemplary embodiment.

FIG. 11 is an equivalent circuit diagram of a shift register according to an exemplary embodiment.

FIG. 12A is a working timing diagram of a shift register according to an exemplary embodiment.

FIG. 12B is a working timing diagram of a shift register according to an exemplary embodiment.

FIG. 13 is an output waveform diagram of a shift register according to an exemplary embodiment.

FIG. 14 is a working timing diagram of a cascade output sub-circuit according to an exemplary embodiment.

FIG. 15A is a schematic diagram of an equivalent circuit of a pixel circuit.

FIG. 15B is a working timing diagram of the pixel circuit provided in FIG. 15A.

FIG. 16A is an equivalent circuit diagram of another pixel circuit.

FIG. 16B is a working timing diagram of the pixel circuit provided in FIG. 16A.

### DETAILED DESCRIPTION

To make objectives, technical solutions, and advantages of the present disclosure clearer, the embodiments of the present disclosure will be described in detail below with reference to the accompanying drawings. It is to be noted that implementation modes may be implemented in multiple different forms. Those of ordinary skills in the art may easily understand such a fact that implementation modes and contents may be transformed into various forms without departing from the purpose and scope of the present disclosure. Therefore, the present disclosure should not be explained as being limited to the contents recorded in the following implementation modes only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings of the embodiments of the present disclosure only involve structures involved in the embodiments of the present disclosure, and for other structures, reference may be made to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation mode of the present disclosure is not limited to shapes, numerical values, or the like shown in the drawings.

Ordinal numerals “first”, “second”, “third”, etc., in the specification are set not to form limitations on numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

In the specification, “disposed in a same layer” adopted refers to a structure formed by patterning two (or more than two) structures through a same patterning process, and their materials may be the same or different. For example, materials of precursors for forming multiple structures disposed in a same layer are the same, and materials finally formed may be the same or different.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, deformation, etc.

In the present disclosure, “about” means that a boundary is not defined so strictly and numerical values within process and measurement error ranges are allowed.

OLED display technology has advantages such as high contrast, fast response, and low power consumption. In order to reduce power consumption, low-temperature polysilicon (LTPS) and Indium Gallium Zinc Oxide (IGZO) are combined to achieve low-temperature polycrystalline Oxide (LTPO) display technology. LTPO can achieve low frame rate display and reduce driving power consumption by reducing repeated refreshing of still images. However, when the OLED display updates the picture, it is desired to initialize and write all pixel voltages in one frame. However, in some special pictures, such as Always on Display (AOD), still pictures or images with fewer updates, the majority of pixel voltages on the entire screen do not need to be updated. At this time, the repeated writing of these pixels makes the display consume more power.

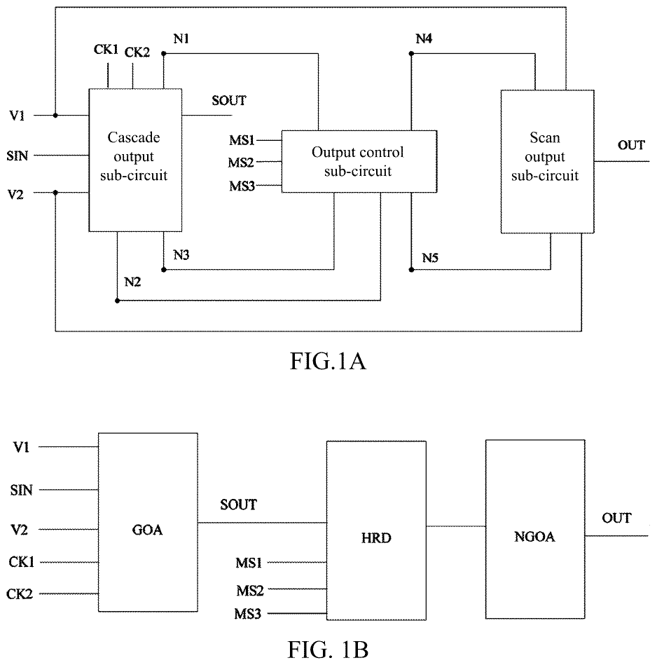

FIG. 1A is a schematic diagram of a structure of a shift register according to an embodiment of the present disclosure, and FIG. 1B is a schematic diagram of a structure of a shift register according to an embodiment of the present disclosure. As shown in FIGS. 1A and 1B, the shift register according to an embodiment of the present disclosure may include a cascade output sub-circuit GOA, an output control sub-circuit HRD, and a scan output sub-circuit NGOA.

The cascade output sub-circuit electrically is connected to an input terminal SIN, an first clock signal terminal CK1, a second clock signal terminal CK2, a first power supply terminal V1, a second power supply terminal V2, a cascade output terminal SOUT, a first node N1, a second node N2, and a third node N3 respectively, and is configured to provide a signal of the first power supply terminal or the second power supply terminal to the cascade output terminal under control of signals of the input terminal, the first clock signal terminal, the second clock signal terminal, the first node, the second node and the third node.

The output control sub-circuit electrically is connected to a first control signal terminal MS1 to a third control signal terminal MS3, the first node N1, the second node N2, the third node N3, a fourth node N4, and a fifth node N5 respectively, and is configured to provide a signal of the first node to the fourth node and provide a signal of the second node to the fifth node under control of signals of the first node, the third node, and the first control signal terminal to the third control signal terminal.

The scan output sub-circuit is electrically connected to the fourth node N4, the fifth node N5, the scan signal output terminal OUT, the first power supply terminal V1, and the second power supply terminal V2 respectively, and is configured to output a signal of the first power supply terminal or the second power supply terminal to the scan signal output terminal under control of signals of the fourth node and the fifth node.

The cascade output sub-circuit GOA outputs a signal of the cascade output terminal SOUT under control of the input terminal SIN, the first clock signal terminal CK1, and the second clock signal terminal CK2, wherein the signal of the cascade output terminal SOUT is the first power supply terminal V1 or the second power supply terminal V2. The output control sub-circuit HRD may select whether to transmit the signal of the first power supply terminal V1 or the second power supply terminal V2 under control of the first control signal terminal MS1 to the third control signal terminal MS3. If a signal of the first power supply terminal V1 is selected to be transmitted under control of the first control signal terminal MS1 to the third control signal terminal MS3, the signal of the first power supply terminal V1 is input to the scan output sub-circuit NGOA, and the signal of the scan signal output terminal OUT output by the scan output sub-circuit NGOA is the signal of the first power supply terminal V1. If a signal of the second power supply terminal V2 is selected to be transmitted under control of the first control signal terminal MS1 to the third control signal terminal MS3, the signal of the cascade output terminal SOUT of the second power supply terminal V2 is input to the scan output sub-circuit NGOA, and the signal of the scan signal output terminal OUT output by the scan output sub-circuit NGOA is the signal of the second power supply terminal V2.

In an exemplary embodiment, the first power supply terminal V1 continuously provides a high-level signal, and the second power supply terminal V2 continuously provides a low-level signal.

In an exemplary embodiment, signals of the first clock signal terminal CK1 and the second clock signal terminal CK2 may be periodic pulse signals.

The shift register according to an embodiment of the present disclosure includes a cascade output sub-circuit, an output control sub-circuit, and a scan output sub-circuit, and the shift register is electrically connected to an input terminal SIN, a first clock signal terminal CK1, a second clock signal terminal CK2, a first power supply terminal V1, a second power supply terminal V2, a scan signal output terminal OUT, and a first control signal terminal MS1 to a third control signal terminal MS3. The cascade output sub-circuit provides a signal of the first power supply terminal or the second power supply terminal to the cascade output terminal under control of signals of the input terminal, the first clock signal terminal, the second clock signal terminal, the first node, the second node and the third node. The output control sub-circuit provides a signal of the first node to the fourth node and a signal of the second node to the fifth node under control of signals of the first node, the third node and the first control signal terminal to the third control signal terminal. The scan output sub-circuit outputs a signal of the first power supply terminal or the second power supply terminal to the scan signal output terminal under control of signals of the fourth node and the fifth node. In the embodiment of the present disclosure, by providing the output control sub-circuit, the scan signal output terminal of the scan output sub-circuit can be controlled to output or not to output, thereby reducing power consumption.

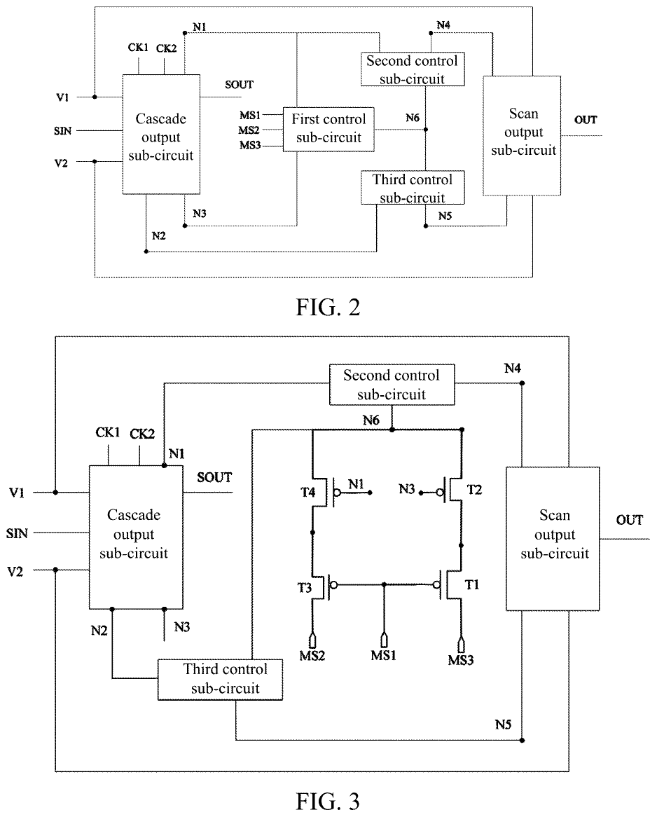

FIG. 2 is an equivalent circuit diagram of an output control sub-circuit according to an exemplary embodiment. As shown in FIG. 2, in an exemplary embodiment, the output control sub-circuit may include a first control sub-circuit, a second control sub-circuit, and a third control sub-circuit.

In an exemplary embodiment, as shown in FIG. 2, the first control sub-circuit is electrically connected to the first node N1, the third node N3, the sixth node N6, and the first to third control signal terminals MS1 to MS3 respectively, and is configured to provide a signal of the second control signal terminal MS2 or the third control signal terminal MS3 to the sixth node under control of signals of the first node, the third node, and the first control signal terminal. The second control sub-circuit is electrically connected to the first node N1, the fourth node N4, and the sixth node N6 respectively, and is configured to provide a signal of the first node to the fourth node under control of a signal of the sixth node. The third control sub-circuit is electrically connected to the second node N2, the fifth node N5, and the sixth node N6 respectively, and is configured to provide a signal of the second node to the fifth node under control of a signal of the sixth node.

An exemplary structure of the output control sub-circuit is shown in FIG. 2. It will be readily understood by those skilled in the art that implementation modes of the output control sub-circuit are not limited thereto.

FIG. 3 is an equivalent circuit diagram of a first control sub-circuit accordance to an exemplary embodiment. As shown in FIG. 3, in an exemplary embodiment, the first control sub-circuit may include a first transistor T1, a second transistor T2, a third transistor T3, and a fourth transistor T4.

In an exemplary embodiment, as shown in FIG. 3, a control electrode of the first transistor T1 is electrically connected to the first control signal terminal MS1, a first electrode of the first transistor T1 is electrically connected to a second electrode of the second transistor T2, and a second electrode of the first transistor T1 is electrically connected to the third control signal terminal MS3. A control electrode of the second transistor T2 is electrically connected to the third node N3, and a first electrode of the second transistor T2 is electrically connected to the sixth node N6. A control electrode of the third transistor T3 is electrically connected to the first control signal terminal MS1, a first electrode of the third transistor T3 is electrically connected to the second control signal terminal MS2, and a second electrode of the third transistor T3 is electrically connected to a first electrode of the fourth transistor T4. A control electrode of the fourth transistor is electrically connected to the first node N1, and a second electrode of the fourth transistor is electrically connected to the sixth node N6.

An exemplary structure of the first control sub-circuit is shown in FIG. 3. It will be readily understood by those skilled in the art that implementation modes of the first control sub-circuit are not limited thereto.

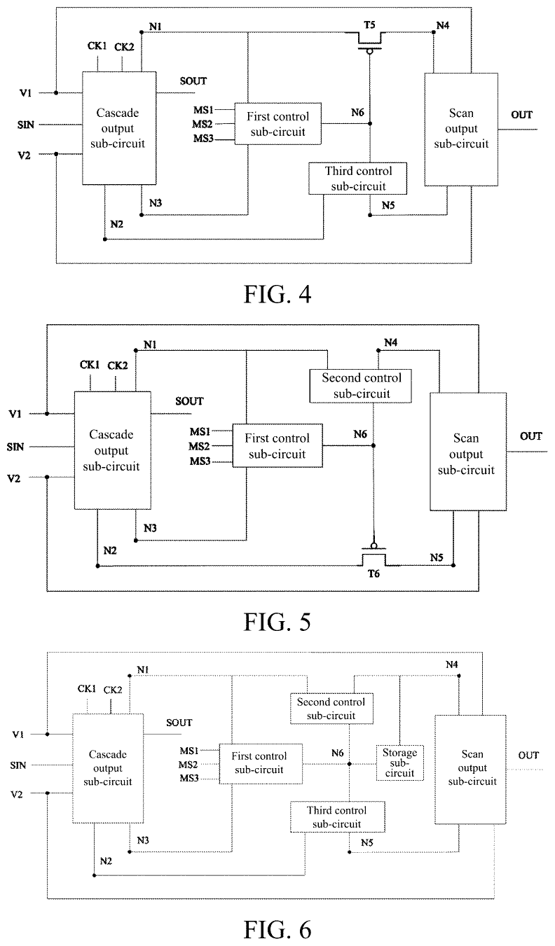

FIG. 4 is an equivalent circuit diagram of a second control sub-circuit according to an exemplary embodiment. As shown in FIG. 4, in an exemplary embodiment, the second control sub-circuit may include a fifth transistor T5.

In an exemplary embodiment, as shown in FIG. 4, a control electrode of the fifth transistor T5 is electrically connected to the sixth node N6, a first electrode of the fifth transistor T5 is electrically connected to the first node N1, and a second electrode of the fifth transistor T5 is electrically connected to the fourth node N4.

An exemplary structure of the second control sub-circuit is shown in FIG. 4. It will be readily understood by those skilled in the art that implementation modes of the second control sub-circuit are not limited thereto.

FIG. 5 is an equivalent circuit diagram of a third control sub-circuit according to an exemplary embodiment. As shown in FIG. 5, in an exemplary embodiment, the third control sub-circuit includes a sixth transistor T6.

In an exemplary embodiment, as shown in FIG. 5, a control electrode of the sixth transistor T6 is electrically connected to the sixth node N6, a first electrode of the sixth transistor T6 is electrically connected to the second node N2, and a second electrode of the sixth transistor T6 is electrically connected to the fifth node N5.

An exemplary structure of a third control sub-circuit is shown in FIG. 5. It will be readily understood by those skilled in the art that the implementation mode of the third control sub-circuit is not limited thereto.

FIG. 6 is an equivalent circuit diagram of an output control sub-circuit according to an exemplary embodiment. As shown in FIG. 6, in an exemplary embodiment, the output control sub-circuit may further include a storage sub-circuit.

In an exemplary embodiment, as shown in FIG. 6, the storage sub-circuit electrically is connected to the fourth node N4 and the sixth node N6 respectively, and is configured to store a voltage difference between signals of the sixth node and the fourth node.

An exemplary structure of the output control sub-circuit is shown in FIG. 6. It will be readily understood by those skilled in the art that implementation modes of the output control sub-circuit are not limited thereto.

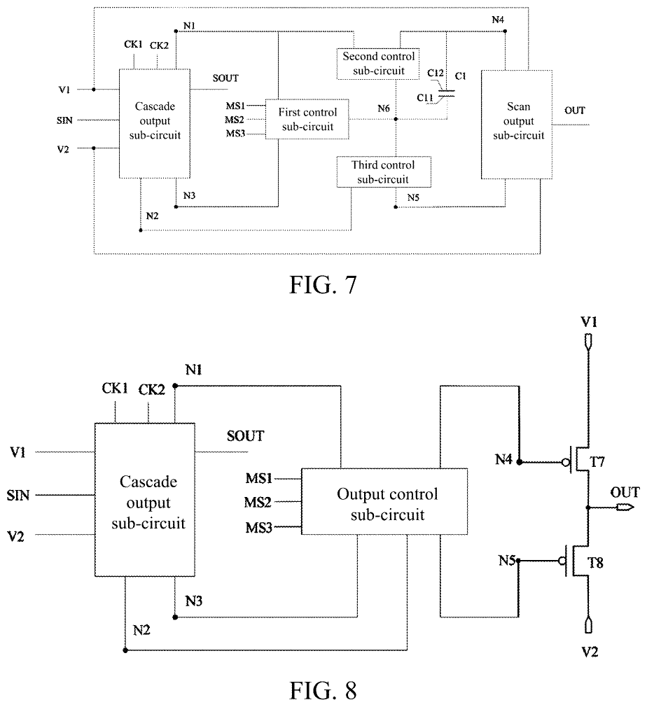

FIG. 7 is an equivalent circuit diagram of a storage sub-circuit according to an exemplary embodiment. As shown in FIG. 7, in an exemplary embodiment, the storage sub-circuit may include a first capacitor C1 including a first plate C11 and a second plate C12.

In an exemplary embodiment, as shown in FIG. 7, the first plate C11 of the first capacitor C1 is electrically connected to the sixth node N6, and the second plate C12 of the first capacitor C1 is electrically connected to the fourth node N4.

FIG. 8 is an equivalent circuit diagram of a scan output sub-circuit according to an exemplary embodiment. As shown in FIG. 8, in an exemplary embodiment, the scan output sub-circuit may include a seventh transistor T7 and an eighth transistor T8.

In an exemplary embodiment, as shown in FIG. 8, a control electrode of the seventh transistor T7 is electrically connected to the fourth node N4, a first electrode of the seventh transistor T7 is electrically connected to the first power supply terminal V1, and a second electrode of the seventh transistor T7 is electrically connected to the scan signal output terminal OUT. A control electrode of the eighth transistor T8 is electrically connected to the fifth node N5, a first electrode of the eighth transistor T8 is electrically connected to the scan signal output terminal OUT, and a second electrode of the eighth transistor T8 is electrically connected to the second power supply terminal V2.

An exemplary structure of the scan output sub-circuit is shown in FIG. 8. It will be readily understood by those skilled in the art that implementation modes of the scan output sub-circuit are not limited thereto.

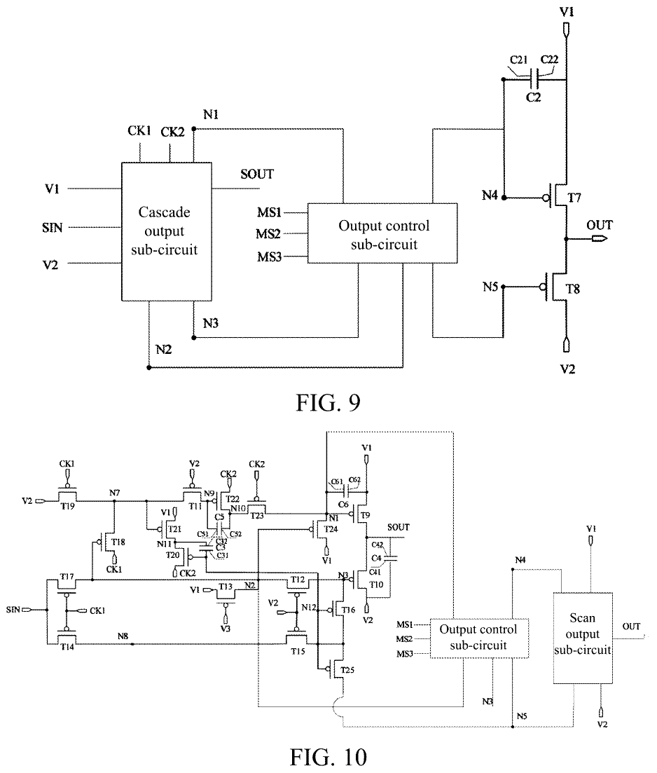

FIG. 9 is an equivalent circuit diagram of a scan output sub-circuit according to an exemplary embodiment. As shown in FIG. 9, in an exemplary embodiment, the scan output sub-circuit may further include a second capacitor C2 including a first plate C21 and a second plate C22.

In an exemplary embodiment, as shown in FIG. 9, the first plate C21 of the second capacitor C2 is electrically connected to the fourth node N4, and the second plate C22 of the second capacitor C2 is electrically connected to the first power supply terminal V1.

An exemplary structure of the scan output sub-circuit is shown in FIG. 9. It will be readily understood by those skilled in the art that implementation modes of the scan output sub-circuit are not limited thereto.

FIG. 10 is an equivalent circuit diagram of a cascade output sub-circuit according to an exemplary embodiment. As shown in FIG. 10, in an exemplary embodiment, the cascade output sub-circuit may include a ninth transistor T9 to a twenty-fifth transistor T25, and a third capacitor C3 to a sixth capacitor C6.

In an exemplary embodiment, as shown in FIG. 10, a control electrode of the ninth transistor T9 is electrically connected to the first node N1, a first electrode of the ninth transistor T9 is electrically connected to the first power supply terminal V1, and a second electrode of the ninth transistor T9 is electrically connected to the cascade output terminal SOUT. A control electrode of the tenth transistor T10 is electrically connected to the third node N3, a first electrode of the tenth transistor T10 is electrically connected to the second power supply terminal V2, and a second electrode of the tenth transistor T10 is electrically connected to the cascade output terminal SOUT. A control electrode of the eleventh transistor T11 is electrically connected to the second power supply terminal V2, a first electrode of the eleventh transistor T11 is electrically connected to a seventh node N7, and a second electrode of the eleventh transistor T11 is electrically connected to a ninth node N9. A control electrode of the twelfth transistor T12 is electrically connected to the second power supply terminal V2, a first electrode of the twelfth transistor T12 is electrically connected to the second node N2, and a second electrode of the twelfth transistor T12 is electrically connected to the third node N3. A control electrode of the thirteenth transistor T13 is electrically connected to the third power supply terminal V3, a first electrode of the thirteenth transistor T13 is electrically connected to the first power supply terminal V1, and a second electrode of the thirteenth transistor T13 is electrically connected to the second node N2. A control electrode of the fourteenth transistor T14 is electrically connected to the first clock signal terminal CK1, a first electrode of the fourteenth transistor T14 is electrically connected to the input terminal SIN, and a second electrode of the fourteenth transistor T14 is electrically connected to an eighth node N8. A control electrode of the fifteenth transistor T15 is electrically connected to the second power supply terminal V2, a first electrode of the fifteenth transistor T15 is electrically connected to the eighth node N8, and a second electrode of the fifteenth transistor T15 is electrically connected to a twelfth node N12. A control electrode of the sixteenth transistor T16 is electrically connected to the twelfth node N12, a first electrode of the sixteenth transistor T16 is electrically connected to the third node N3, and a second electrode of the sixteenth transistor T16 is electrically connected to the twelfth node N12. A control electrode of the seventeenth transistor T17 is electrically connected to the first clock signal terminal CK1, a first electrode of the seventeenth transistor T17 is electrically connected to the input terminal SIN, and a second electrode of the seventeenth transistor T17 is electrically connected to the second node N2. A control electrode of the eighteenth transistor T18 is electrically connected to the second node N2, a first electrode of the eighteenth transistor T18 is electrically connected to the first clock signal terminal CK1, and a second electrode of the eighteenth transistor T18 is electrically connected to the seventh node N7. A control electrode of the nineteenth transistor T19 is electrically connected to the first clock signal terminal CK1, a first electrode of the nineteenth transistor T19 is electrically connected to the second power supply terminal V2, and a second electrode of the nineteenth transistor T19 is electrically connected to the seventh node N7. A control electrode of the twentieth transistor T20 is electrically connected to the second node N2, a first electrode of the twentieth transistor T20 is electrically connected to the second clock signal terminal CK2, and a second electrode of the twentieth transistor T20 is electrically connected to an eleventh node N11. A control electrode of the twenty-first transistor T21 is electrically connected to the seventh node N7, a first electrode of the twenty-first transistor T21 is electrically connected to the first power supply terminal V1, and a second electrode of the twenty-first transistor T21 is electrically connected to the eleventh node N11. A control electrode of the twenty-second transistor T22 is electrically connected to the ninth node N9, a first electrode of the twenty-second transistor T22 is electrically connected to the second clock signal terminal CK2, and a second electrode of the twenty-second transistor T22 is electrically connected to a tenth node N10. A control electrode of the twenty-third transistor T23 is electrically connected to the second clock signal terminal CK2, a first electrode of the twenty-third transistor T23 is electrically connected to the tenth node N10, and a second electrode of the twenty-third transistor T23 is electrically connected to the first node N1. A control electrode of the twenty-fourth transistor T24 is electrically connected to the second node N2, a first electrode of the twenty-fourth transistor T24 is electrically connected to the first power supply terminal V1, and a second electrode of the twenty-fourth transistor T24 is electrically connected to the first node N1. A control electrode of the twenty-fifth transistor T25 is electrically connected to the twelfth node N12, a first electrode of the twenty-fifth transistor T25 is electrically connected to the twelfth node N12, and a second electrode of the twenty-fifth transistor T25 is electrically connected to the fifth node N5. A first plate C31 of the third capacitor C3 is electrically connected to the third node N3, and a second plate C32 of the third capacitor C3 is electrically connected to the eleventh node N11. The fourth capacitor C4 includes a first plate C41 and a second plate C42, the first plate C41 of the fourth capacitor C4 is electrically connected to the second power supply terminal V2, and the second plate C42 of the fourth capacitor C4 is electrically connected to the cascade output terminal SOUT. A first plate C51 of the fifth capacitor C5 is electrically connected to the ninth node N9, and a second plate C52 of the fifth capacitor C5 is electrically connected to the tenth node N10. A first plate C61 of the sixth capacitor C6 is electrically connected to the first node N1, and a second plate C62 of the sixth capacitor C6 is electrically connected to the first power supply terminal V1.

An exemplary structure of a cascade output sub-circuit of a shift register of model 16T3C is shown in FIG. 10. It will be readily understood by those skilled in the art that implementation modes of the cascade output sub-circuit are not limited thereto.

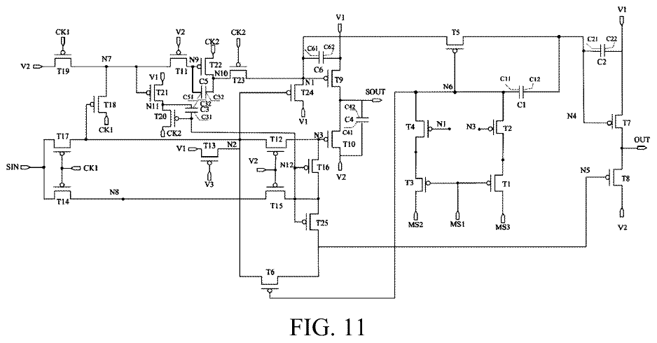

In an exemplary embodiment, the model of the shift register may be 12T3C. When the model of the shift register is 12T3C, the cascade output sub-circuit may include the ninth transistor T9 to the thirteenth transistor T13 and the seventeenth transistor T17 to the twenty-third transistor T23 in FIG. 10 or FIG. 11.

In an exemplary embodiment, the model of the shift register may be 10T3C. When the model of the shift register is 10T3C, the cascade output sub-circuit may include a ninth transistor T9 to a twelfth transistor T12 and a seventeenth transistor T17 to a twenty-second transistor T22.

In an exemplary embodiment, the first transistor T1 to the twenty-fifth transistor T25 may be p-type transistors or may be N-type transistors.

In an exemplary embodiment, the first power supply terminal V1 continuously provides a high-level signal, and the second power supply terminal V2 continuously provides a low-level signal. The eleventh transistor T11, the twelfth transistor T12, and the fifteenth transistor T15 are continuously turned on since the second power supply terminal V2 continuously provides the low-level signal.

In an exemplary embodiment, the third power supply terminal V3 provides a low-level signal during startup initialization stage, which prevents the ninth transistor T9 and the tenth transistor T10 of a control shift register in a last stage from simultaneously being turned on because of delay of an output signal, or is a low-level signal during abnormal shutdown stage, which prevents the ninth transistor T9 and the tenth transistor T10 from simultaneously being turned on. The third power supply terminal V3 continuously provides a high-level signal in a normal display stage, i.e., the thirteenth transistor T13 is continuously turned off in the normal display stage.

FIG. 11 is an equivalent circuit diagram of a shift register according to an exemplary embodiment. As shown in FIG. 11, in an exemplary embodiment, the shift register may include a cascade output sub-circuit, an output control sub-circuit, and a scan output sub-circuit. The cascade output sub-circuit may include a ninth transistor T9 to a twenty-fifth transistor T25, a third capacitor C3 to a sixth capacitor C6, the output control sub-circuit may include a first transistor T1 to a sixth transistor T6 and a first capacitor C1, and the scan output sub-circuit may include a seventh transistor T7, an eighth transistor T8, and a second capacitor C2.

In an exemplary embodiment, as shown in FIG. 11, a control electrode of the first transistor T1 is electrically connected to the first control signal terminal MS1, a first electrode of the first transistor T1 is electrically connected to a second electrode of the second transistor T2, and a second electrode of the first transistor T1 is electrically connected to the third control signal terminal MS3. A control electrode of the second transistor T2 is electrically connected to the third node N3, and a first electrode of the second transistor T2 is electrically connected to the sixth node N6. A control electrode of the third transistor T3 is electrically connected to the first control signal terminal MS1, a first electrode of the third transistor T3 is electrically connected to the second control signal terminal MS2, and a second electrode of the third transistor T3 is electrically connected to a first electrode of the fourth transistor T4. A control electrode of the fourth transistor is electrically connected to the first node N1, and a second electrode of the fourth transistor is electrically connected to the sixth node N6. A control electrode of the fifth transistor T5 is electrically connected to the sixth node N6, a first electrode of the fifth transistor T5 is electrically connected to the first node N1, and a second electrode of the fifth transistor T5 is electrically connected to the fourth node N4. A control electrode of the sixth transistor T6 is electrically connected to the sixth node N6, a first electrode of the sixth transistor T6 is electrically connected to the second node N2, and a second electrode of the sixth transistor T6 is electrically connected to the fifth node N5. A control electrode of the seventh transistor T7 is electrically connected to the fourth node N4, a first electrode of the seventh transistor T7 is electrically connected to the first power supply terminal V1, and a second electrode of the seventh transistor T7 is electrically connected to the scan signal output terminal OUT. A control electrode of the eighth transistor T8 is electrically connected to the fifth node N5, a first electrode of the eighth transistor T8 is electrically connected to the scan signal output terminal OUT, and a second electrode of the eighth transistor T8 is electrically connected to the second power supply terminal V2. A control electrode of the ninth transistor T9 is electrically connected to the first node N1, a first electrode of the ninth transistor T9 is electrically connected to the first power supply terminal V1, and a second electrode of the ninth transistor T9 is electrically connected to the cascade output terminal SOUT. A control electrode of the tenth transistor T10 is electrically connected to the third node N3, a first electrode of the tenth transistor T10 is electrically connected to the second power supply terminal V2, and a second electrode of the tenth scan transistor T10 is electrically connected to the cascade output terminal SOUT. A control electrode of the eleventh transistor T11 is electrically connected to the second power supply terminal V2, a first electrode of the eleventh transistor T11 is electrically connected to the seventh node N7, and a second electrode of the eleventh transistor T11 is electrically connected to the ninth node N9. A control electrode of the twelfth transistor T12 is electrically connected to the second power supply terminal V2, a first electrode of the twelfth transistor T12 is electrically connected to the second node N2, and a second electrode of the twelfth transistor T12 is electrically connected to the third node N3. A control electrode of the thirteenth transistor T13 is electrically connected to the third power supply terminal V3, a first electrode of the thirteenth transistor T13 is electrically connected to the first power supply terminal V1, and a second electrode of the thirteenth transistor T13 is electrically connected to the second node N2. A control electrode of a fourteenth transistor T14 is electrically connected to the first clock signal terminal CK1, a first electrode of the fourteenth transistor T14 is electrically connected to the input terminal SIN, and a second electrode of the fourteenth transistor T14 is electrically connected to the eighth node N8. A control electrode of the fifteenth transistor T15 is electrically connected to the second power supply terminal V2, a first electrode of the fifteenth transistor T15 is electrically connected to the eighth node N8, and a second electrode of the fifteenth transistor T15 is electrically connected to the twelfth node N12. A control electrode of the sixteenth transistor T16 is electrically connected to the twelfth node N12, a first electrode of the sixteenth transistor T16 is electrically connected to the third node N3, and a second electrode of the sixteenth transistor T16 is electrically connected to the twelfth node N12. A control electrode of the seventeenth transistor T17 is electrically connected to the first clock signal terminal CK1, a first electrode of the seventeenth transistor T17 is electrically connected to the input terminal SIN, and a second electrode of the seventeenth transistor T17 is electrically connected to the second node N2. A control electrode of the eighteenth transistor T18 is electrically connected to the second node N2, a first electrode of the eighteenth transistor T18 is electrically connected to the first clock signal terminal CK1, and a second electrode of the eighteenth transistor T18 is electrically connected to the seventh node N7. A control electrode of the nineteenth transistor T19 is electrically connected to the first clock signal terminal CK1, a first electrode of the nineteenth transistor T19 is electrically connected to the second power supply terminal V2, and a second electrode of the nineteenth transistor T19 is electrically connected to the seventh node N7. A control electrode of the twentieth transistor T20 is electrically connected to the second node N2, a first electrode of the twentieth transistor T20 is electrically connected to the second clock signal terminal CK2, and a second electrode of the twentieth transistor T20 is electrically connected to the eleventh node N11. A control electrode of the twenty-first transistor T21 is electrically connected to the seventh node N7, a first electrode of the twenty-first transistor T21 is electrically connected to the first power supply terminal V1, and a second electrode of the twenty-first transistor T21 is electrically connected to the eleventh node N11. A control electrode of the twenty-second transistor T22 is electrically connected to the ninth node N9, a first electrode of the twenty-second transistor T22 is electrically connected to the second clock signal terminal CK2, and a second electrode of the twenty-second transistor T22 is electrically connected to the tenth node N10. A control electrode of the twenty-third transistor T23 is electrically connected to the second clock signal terminal CK2, a first electrode of the twenty-third transistor T23 is electrically connected to the tenth node N10, and a second electrode of the twenty-third transistor T23 is electrically connected to the first node N1. A control electrode of the twenty-fourth transistor T24 is electrically connected to the second node N2, a first electrode of the twenty-fourth transistor T24 is electrically connected to the first power supply terminal V1, and a second electrode of the twenty-fourth transistor T24 is electrically connected to the first node N1. A control electrode of the twenty-fifth transistor T25 is electrically connected to the twelfth node N12, a first electrode of the twenty-fifth transistor T25 is electrically connected to the twelfth node N12, and a second electrode of the twenty-fifth transistor T25 is electrically connected to the fifth node N5. A first plate C11 of the first capacitor C1 is electrically connected to the sixth node N6, and a second plate C12 of the first capacitor C1 is electrically connected to the fourth node N4. A first plate C21 of the second capacitor C2 is electrically connected to the fourth node N4, and a second plate C22 of the second capacitor C2 is electrically connected to the first power supply terminal V1. A first plate C31 of the third capacitor C3 is electrically connected to the third node N3, and a second plate C32 of the third capacitor C3 is electrically connected to the eleventh node N11. The fourth capacitor C4 includes a first plate C41 and a second plate C42, the first plate C41 of the fourth capacitor C4 is electrically connected to the second power supply terminal V2, and the second plate C42 of the fourth capacitor C4 is electrically connected to the cascade output terminal SOUT. A first plate C51 of the fifth capacitor C5 is electrically connected to the ninth node N9, and a second plate C52 of the fifth capacitor C5 is electrically connected to the tenth node N10. A first plate C61 of the sixth capacitor C6 is electrically connected to the first node N1, and a second plate C62 of the sixth capacitor C6 is electrically connected to the first power supply terminal V1.

An exemplary structure of a shift register of model 16T3C is shown in FIG. 11. It will be readily understood by those skilled in the art that implementation modes of the shift register are not limited thereto.

In an exemplary embodiment, the model of the shift register may be 12T3C. When the model of the shift register is 12T3C, the cascade output sub-circuit may include the ninth transistor T9 to the thirteenth transistor T13 and the seventeenth transistor T17 to the twenty-third transistor T23 in FIG. 10 or FIG. 11.

In an exemplary embodiment, the model of the shift register may be 10T3C. When the model of the shift register is 10T3C, the cascade output sub-circuit may include a ninth transistor T9 to a twelfth transistor T12 and a seventeenth transistor T17 to a twenty-second transistor T22.

In an exemplary embodiment, the shift register is provided on a display substrate, the display substrate may include: a plurality of scan signal lines, and a working process of the display substrate may include: a display stage and a blank stage between the display stages. The display substrate may include a plurality of display regions, and refresh frequencies of different display regions include a first refresh frequency and a second refresh frequency, wherein the first refresh frequency is greater than the second refresh frequency.

In a state in which the working process of the display substrate is in the blank stage, when a signal of the first control signal terminal MS1 is a low-level signal, signals of the second control signal terminal MS2 and the third control signal terminal MS3 are low-level signals.

In a state in which the working process of the display substrate is in the display stage and the shift register is connected to a scan signal line located in a display region at the first refresh frequency, when the signal of the first control signal terminal MS1 is a low-level signal, the signals of the second control signal terminal MS2 and the third control signal terminal MS3 are low-level signals.

In a state in which the working process of the display substrate is in the display stage, the shift register is connected to a scan signal line located in a display region at the second refresh frequency, and the cascade output terminal SOUT of the shift register outputs a low-level signal, when the signal of the first control signal terminal MS1 is a low-level signal, the signal of the second control signal terminal MS2 is a high-level signal, and the signal of the third control signal terminal MS3 is a low-level signal.

In a state in which the working process of the display substrate is in the display stage, the shift register is connected to a scan signal line located in a display region at the second refresh frequency, and the cascade output terminal SOUT of the shift register outputs a high-level signal, when the signal of the first control signal terminal MS1 is a low-level signal, the signal of the second control signal terminal MS2 is a high-level signal, and the signal of the third control signal terminal MS3 is a low-level signal.

In a state in which the working process of the display substrate is in a display stage, the shift register is connected to a scan signal line located in a display region at the second refresh frequency, and the cascade output terminal SOUT of the shift register outputs a low-level signal, when the signal of the first control signal terminal MS1 is a low-level signal, the signal of the second control signal terminal MS2 is a high-level signal, and the signal of the third control signal terminal MS3 is a low-level signal.

A duration during which the signal of the first control signal terminal MS1 is a low-level signal is less than a duration during which either one of the signal of the second control signal terminal MS2 and the signal of the third control signal terminal MS3 is a low-level signal.

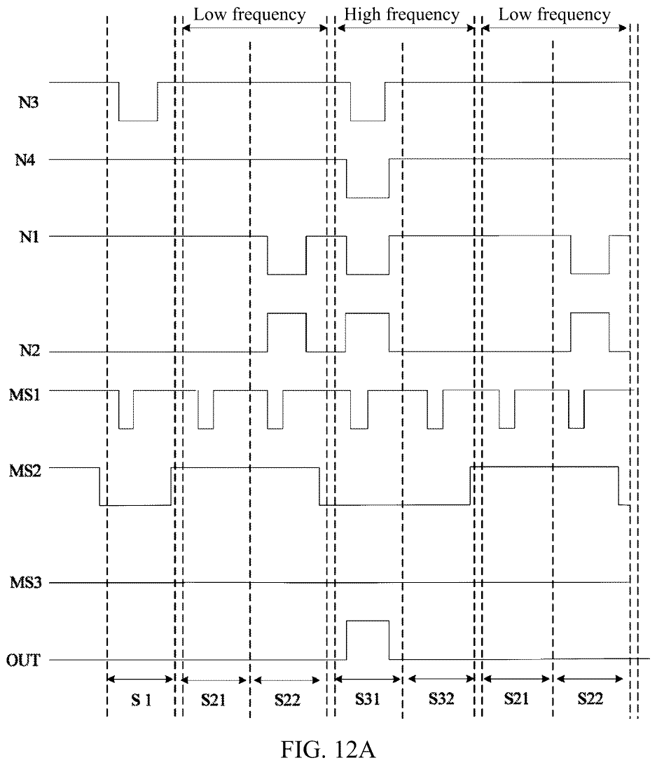

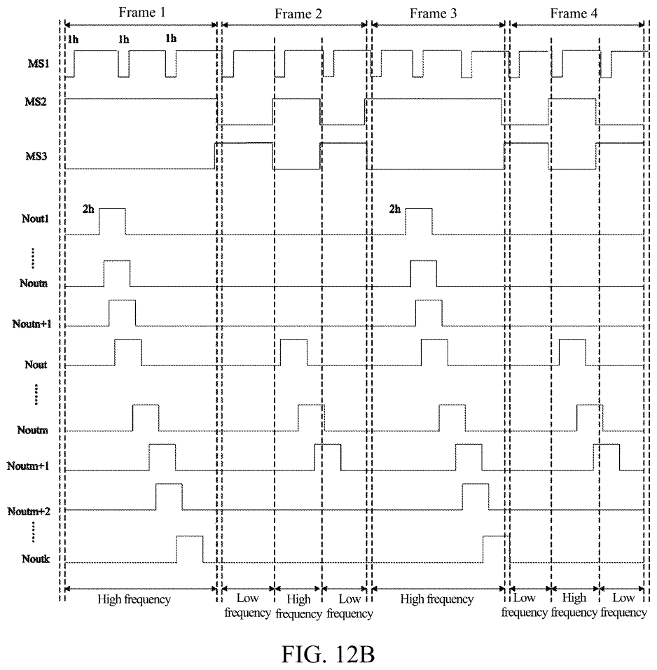

FIG. 12A is a working timing diagram of a shift register according to an exemplary embodiment, and an exemplary embodiment of the present disclosure will be described below with reference to the working process of the shift register illustrated in FIG. 11, taking the first transistor T1 to the eighth transistor T8, the first capacitor C1, the second capacitor C2, the first control signal terminal MS1 to the third control signal terminal MS3, the first node N1 to the fourth node N4, and the scan signal output terminal OUT in the shift register provided in FIG. 11 as an example.

In an exemplary example, as shown in FIG. 12A, a working process of the shift register may include the following stages.

S1 stage (initialization stage): a signal of the first node N1 is a high-level signal, and signals of the third node N3, the first control signal terminal MS1, the second control signal terminal MS2, and the third control signal terminal MS3 are low-level signals. The signal of the first control signal terminal MS1 is the low-level signal, the first transistor T1 is turned on, the signal of the third node N3 is a low-level signal, the second transistor T2 is turned on, and the low-level signal of the third control signal terminal MS3 is written to the sixth node N6 through the first transistor T1 and second transistor T2 which are turned-on. A signal of the sixth node N6 is a low-level signal and is held by the first capacitor C1, and the fifth transistor T5 and the sixth transistor T6 are turned on. The high-level signal of the first node N1 is written to the fourth node N4 through the turned-on fifth transistor T5, at this time, the seventh transistor T7 is turned off, and the low-level signal of the third node N3 is written to the fifth node N5 through the turned-on sixth transistor T6, at this time, the eighth transistor T8 is turned on, and a low-level signal of the second power supply terminal V2 is written to the scan signal output terminal OUT, and an output signal of the scan signal output terminal OUT is a low-level signal.

Stage S21 (an output of the cascade output terminal SOUT in a low-frequency region at a low level): signals of the first node N1 and the second control signal terminal MS2 are high-level signals, and signals of the third node N3, the first control signal terminal MS1 and the third control signal terminal MS3 are low-level signals. The signal of the first control signal terminal MS1 is the low-level signal, the first transistor T1 is turned on, the third node N3 at a low level, the second transistor T2 is turned on, and the low-level signal of the third control signal terminal MS3 is written to the sixth node N6 through the first transistor T1 and second transistor T2 which are turned-on. The signal of the sixth node N6 is a low-level signal and is held by the first capacitor C1, and the fifth transistor T5 and the sixth transistor T6 are turned on. The high-level signal of the first node N1 is written to the fourth node N4 through the turned-on fifth transistor T5, at this time, the seventh transistor T7 is turned off, and the low-level signal of the third node N3 is written to the fifth node N5 through the turned-on sixth transistor T6, at this time, the eighth transistor T8 is turned on, and the low-level signal of the second power supply terminal V2 is written to the scan signal output terminal OUT, and the output signal of the scan signal output terminal OUT is a low-level signal.

Stage S22 (the output of the cascade output terminal SOUT in a low-frequency region is at a high level): signals of the first node N1, the first control signal terminal MS1 and the third control signal terminal MS3 are low-level signals, and signals of the third node N3 and the second control signal terminal MS2 are high-level signals. The signal of the first control signal terminal MS1 is a low-level signal, the third transistor T3 is turned on, the signal of the first node N1 is a low-level signal, the fourth transistor T4 is turned on, and the high-level signal of the second control signal terminal MS2 is written to the sixth node N6 through the third transistor T3 and fourth transistor T4 which are turned-on. The signal of the sixth node N6 is a high-level signal and is held by the first capacitor C1. The high-level signal of the previous stage of the fourth node N4 is held by the second capacitor C2, and at this time, the seventh transistor T7 is turned off. The fifth node N5 remains a low-level signal, at this time, the eighth transistor T8 is turned on, the low-level signal of the second power supply terminal V2 is written to the scan signal output terminal OUT, and the output signal of the scan signal output terminal OUT is a low-level signal.

Stage S31 (the output of the cascade output terminal SOUT in a high-frequency region is at a high level): signals of the first node N1, the first control signal terminal MS1, the second control signal terminal MS2, and the third control signal terminal MS3 are low-level signals, and the signal of the third node N3 is a high-level signal. The signal of the first control signal terminal MS1 is a low-level signal, the third transistor T3 is turned on, the first node N1 is at a low level, the fourth transistor T4 is turned on, and the low-level signal of the second control signal terminal MS2 is written to the sixth node N6 through the third transistor T3 and fourth transistor T4 which are turned-on. The signal of the sixth node N6 is a low-level signal and is held by the first capacitor C1, and the fifth transistor T5 and the sixth transistor T6 are turned on. The high-level signal of the third node N3 is written to the fifth node N5 through the turned-on sixth transistor T6, and at this time, the eighth transistor T8 is turned off. The low-level signal of the first node N1 is written to the fourth node N4 through the turned-on fifth transistor T5, at this time, the seventh transistor T7 is turned on, and the high-level signal of the first power supply terminal V1 is written to the scan signal output terminal OUT, and the output signal of the scan signal output terminal OUT is a high-level signal.

Stage S32 (the output of the cascade output terminal SOUT in a high-frequency region at a low level): the signal of the first node N1 is a high-level signal, and signals of the third node N3, the first control signal terminal MS1, the second control signal terminal MS2, and the third control signal terminal MS3 are low-level signals. The first control signal terminal MS1 is a low-level signal, the first transistor T1 is turned on, the third node N3 at a low level, the second transistor T2 is turned on, and the low-level signal of the third control signal terminal MS3 is written to the sixth node N6 through the turned-on first transistor T1 and second transistor T2. The signal of the sixth node N6 is a low-level signal and is held by the first capacitor C1, and the fifth transistor T5 and the sixth transistor T6 are turned on. The high-level signal of the first node N1 is written to the fourth node N4 through the turned-on fifth transistor T5, at this time, the seventh transistor T7 is turned off, and the low-level signal of the third node N3 is written to the fifth node N5 through the turned-on sixth transistor T6, at this time, the eighth transistor T8 is turned on, and the low-level signal of the second power supply terminal V2 is written to the scan signal output terminal OUT, and the output signal of the scan signal output terminal OUT is a low-level signal.

FIG. 12B is a working timing diagram of a shift register according to an exemplary embodiment, and an exemplary embodiment of the present disclosure will be described below with reference to a working process of the shift register illustrated in FIG. 11, taking the first transistor T1 to the eighth transistor T8, the first capacitor C1, the second capacitor C2, the first control signal terminal MS1 to the third control signal terminal MS3, and the scan signal output terminal OUT in the shift register provided in FIG. 11 as an example, the scan signal output terminal OUT includes scan signal output terminals Nout1 . . . Nout n, Nout n+1, Nout . . . Nout m, Nout m+1, Nout m+2 . . . Nout k for different frames.

In an exemplary embodiment, as shown in FIG. 12B, by altering voltages of the control signals MS (first control signal terminal MS1, second control signal terminal MS2, and third control signal terminal MS3), it is possible to control whether or not a low-level signal of the scan signal output terminal OUT is output, which can control the high-level output of the scan signal output terminal within one frame, update the data voltage Vdata for some lines, and control the refresh of local pictures in different frames, thereby reducing the power consumption of the display panel. However, scan signal output terminals for other lines are always at low level, and the initial signal line and data voltage Vdata will not be repeatedly charged and discharged, thus saving power consumption.

In an exemplary embodiment, as shown in FIG. 12B, the working process of the shift register may be divided into following three stages.

Initialization stage: In the second to last line of the initialization frame, a first pulse of the first control signal terminal MS1 is turned on, at this time, the signal of the third node N3 is a low-level signal, the signal of the first node N1 is a high-level signal, the first transistor T1 and the second transistor T2 are turned on, the fourth transistor T4 is turned off, and the third node N3 is written with a low-level signal of the third control signal terminal MS3 and is held by the first capacitor C1. The fifth transistor T5 and the sixth transistor T6 are turned on, the first node N1 is in communication with the fourth node N4, the second node N2 is in communication with the fifth node N5, and the scan signal output terminals Nout1 . . . Nout n, Nout n+1, Nout . . . Nout m, Nout m+1, Nout m+2 . . . Nout k in different frames can output normally.

High-frequency to low-frequency switching stage: in the last line of a frame in a high-frequency region, a second pulse of the first control signal terminal MS1 is turned on. If the cascade output terminal Sout outputs a low-level signal at this time, that is, the signal of the first node N1 is a high-level signal and the signal of the third node N3 is a low-level signal, the first transistor T1 and the second transistor T2 are turned on, and the sixth node N6 is written with the high-level signal of the third control signal terminal MS3. The fifth transistor T5 and the sixth transistor T6 are turned off, the fourth node N4 holds a high-level signal, and the fifth node N5 holds a low-level signal, which can always maintain the scan signal output terminals Nout1 . . . Nout n, Nout n+1, Nout . . . Nout m, Nout m+1, Nout m+2 . . . Nout k in corresponding different frames at low-level signals. If the cascade output terminal Sout outputs a high-level signal at this time, that is, the signal of the first node N1 is a low-level signal, the signal of the third node N3 is a high-level signal, the second transistor T2 and the fourth transistor T4 are turned on, and the sixth node N6 is written with the low-level signal of the second control signal terminal MS2 and is held by the first capacitor C1. The fifth transistor T5 and the sixth transistor T6 are turned on, the signal of the fourth node N4 still maintains a low-level signal, the signal of the fifth node N5 still maintains a high-level signal, and the scan signal output terminals Nout1 . . . Nout n, Nout n+1, Nout . . . Nout m, Nout m+1, Nout m+2 . . . Nout k in different frames can still output high-level signals. When the output of the cascade output terminal Sout switches to a low level, the scan signal output terminals Nout1 . . . Nout n, Nout n+1, Nout . . . Nout m, Nout m+1, Nout m+2 . . . Nout k in different frames can output low-level signals. In other words, at this time, the scan signal output terminals Nout1 . . . Nout n, Nout n+1, Nout . . . Nout m, Nout m+1, Nout m+2 . . . Nout k in corresponding different frames can keep outputting low-level signals after keep outputting complete high-level waveforms.

Low-frequency to high-frequency switching stage: in the last line of a frame in a low-frequency region, a third pulse of the first control signal terminal MS1 is turned on. If the cascade output terminal Sout outputs a low-level signal at this time, a timing process is the same as that in the initialization stage. The scan signal output terminals Nout1 . . . Nout n, Nout n+1, Nout . . . Nout m, Nout m+1, Nout m+2 . . . Nout k in different frames can output normally. If the cascade output terminal Sout outputs a high-level signal at this time, that is, the signal of the first node N1 is a low-level signal, the signal of the third node N3 is a high-level signal, the second transistor T2 and the fourth transistor T4 are turned on, and the sixth node N6 is written with the high-level signal of the second control signal terminal MS2 and is held by the first capacitor C1. The high-level signal of the previous stage of the fourth node N4 is held by the second capacitor C2, and the fifth node N5 maintains the low-level signal, which can maintain the scan signal output terminals Nout1 . . . Nout n, Nout n+1, Nout . . . Nout m, Nout m+1, Nout m+2 . . . Nout k in corresponding different frames to keep outputting low-level waveforms.

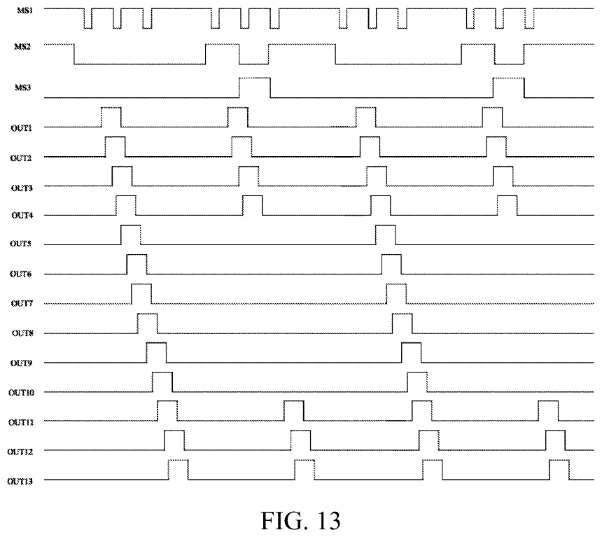

FIG. 13 is an output waveform diagram of a shift register according to an exemplary embodiment, and as shown in FIG. 13, control of scan signal output terminals OUT1 to OUT13 of thirteen lines of pixels can be achieved by switching of voltages of signals of the first control signal terminal MS1, the first control signal terminal MS2, and the third control signal terminal MS3. Herein, the abscissa in FIG. 13 represents time, which can be measured in microseconds (μs, which can be referred to as μ for short).

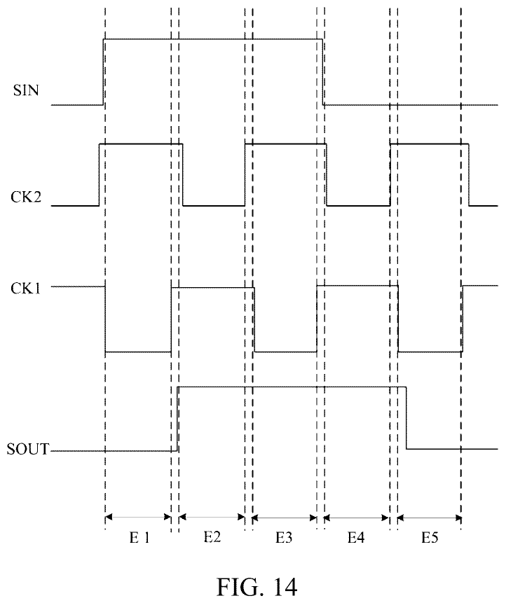

FIG. 14 is a working timing diagram of a cascade output sub-circuit according to an exemplary embodiment, an exemplary embodiment of the present disclosure will be described with reference to a working process of the cascade output sub-circuit exemplified in FIG. 10 or FIG. 11, taking the ninth transistor T9 to the twenty-fifth transistor T25, the third capacitor C3 to the sixth capacitor C6, the input terminal SIN, the first clock signal terminal CK1, the second clock signal terminal CK2, and the cascade output terminal SOUT in the cascade output sub-circuit provided in FIG. 10 or 11 as an example.

In an exemplary embodiment, as shown in FIG. 14, the working process of the cascade output sub-circuit may the following stages.

In a first stage E1, a signal of the second clock signal terminal CK2 is a high-level signal, and a signal of the first clock signal terminal CK1 is a low-level signal. The signal of the first clock signal terminal CK1 is the low-level signal, the seventeenth transistor T17, the nineteenth transistor T19, the twelfth transistor T12, and the fourteenth transistor T14 are turned on, the turned-on seventeenth transistor T17 transmits a high-level signal of the input terminal SIN to the second node N2, a signal of the second node N2 becomes a high-level signal, the turned-on twelfth transistor T12 transmits the high-level signal of the second node N2 to the third node N3, the turned-on fourteenth transistor T14 transmits the high-level signal of the input terminal SIN to the eighth node N8, a signal of the eighth node N8 becomes a high-level signal, the turned-on fifteenth transistor T15 transmits the high-level signal of the eighth node N8 to the twelfth node N12, and the eighteenth transistor T18, the twentieth transistor T20, the twenty-fourth transistor T24, and the tenth transistor T10 are turned off. Further, the turned-on nineteenth transistor T19 transmits a low-level signal of the second power supply terminal V2 to the seventh node N7, and a signal of the seventh node N7 becomes a low-level signal, the turned-on eleventh transistor T11 transmits the low-level signal of the seventh node N7 to the ninth node N9, and a signal of the ninth node N9 becomes a low-level signal, and the twenty-first transistor T21 and the twenty-second transistor T22 are turned on. The signal of the second clock signal terminal CK2 is the high-level signal, and the twenty-third transistor T23 is turned off. In addition, the ninth transistor T9 is turned off under an action of the third capacitor C3. In the first stage E1, since both the ninth transistor T9 and the tenth transistor T10 are turned off, a signal of the cascade output terminal SOUT is maintained at a previous low level.

In a second stage E2, the signal of the second clock signal terminal CK2 is a low-level signal, and the signal of the first clock signal terminal CK1 is a high-level signal. As the signal of the second clock signal terminal CK2 is the low-level signal, the twenty-third transistor T23 is turned on. The signal of the first clock signal terminal CK1 is the high-level signal, and the seventeenth transistor T17 and the nineteenth transistor T19 are turned off. Under an action of the third control capacitor C3, the second node N2, the third node N3, the eighth node N8, and the twelfth node N12 may continue to maintain the high-level signal of a previous stage, and under an action of the fifth capacitor C5, the ninth node N9 may continue to maintain the low level during the previous stage, so the twenty-first transistor T21 and the twenty-second transistor T22 are turned on. The eighteenth transistor T18, the twentieth transistor T20, the twenty-fourth transistor T24, and the tenth transistor T10 are turned off. Further, the low-level signal of the second clock signal terminal CK2 is transmitted to the first node N1 through the twenty-second transistor T22 and the twenty-third transistor T23 which are turned on, the ninth transistor T9 is turned on, the turned-on ninth transistor T9 outputs the high-level signal of the first power supply terminal V1, and the signal of the cascade output terminal SOUT is a high-level signal.

In a third stage E3, the signal of the first clock signal terminal CK1 is a low-level signal, and the signal of the second clock signal terminal CK2 is a high-level signal. The signal of the second clock signal terminal CK2 is the high-level signal, the twenty-third transistor T23 is turned off, and the eighteenth transistor T18, the twentieth transistor T20, the twenty-fourth transistor T24, and the tenth transistor T10 are turned off. The signal of the first clock signal terminal CK1 is the low-level signal, and the seventeenth transistor T17 and the nineteenth transistor T19 are turned on. Under an action of the third capacitor C3, the ninth transistor T9 is kept in a turned-on state, the turned-on control transistor T9 outputs the high-level signal of the first power supply terminal V1, and the signal of the cascade output terminal SOUT is still a high-level signal.

In a fourth stage E4, the signal of the second clock signal terminal CK2 is a low-level signal and the signal of the first clock signal terminal CK1 is a high-level signal. The signal of the first clock signal terminal CK1 is the high-level signal, and the seventeenth transistor T17 and the nineteenth transistor T19 are turned off. As the signal of the second clock signal terminal CK2 is the low-level signal, the twenty-third transistor T23 is turned on. Due to a storage function of the third capacitor C3, signals of the second node N2, the third node N3, the eighth node N8, and the twelfth node N12 maintain the high-level signals of the previous stage, and the eighteenth transistor T18, the twentieth transistor T20, the twenty-fourth transistor T24, and the tenth transistor T10 are turned off. Due to a storage function of the fifth capacitor C5, the ninth node N9 is continuously kept at the low level of the previous stage, and the twenty-first transistor T21 and the twenty-second transistor T22 are turned on. In addition, the low-level signal of the second clock signal terminal CK2 is transmitted to the first node N1 through the twenty-second control transistor T22 and the twenty-third control transistor T23 which are turned-on, the turned-on ninth transistor T9 outputs the high-level signal of the first power supply terminal V1, and the signal of the cascade output terminal SOUT is still a high-level signal.

In a fifth stage E5, the signal of the second clock signal terminal CK2 is a high-level signal and the signal of the first clock signal terminal CK1 is a low-level signal. The signal of the first clock signal terminal CK1 is the low-level signal, and the seventeenth transistor T17, the nineteenth transistor T19, and the fourteenth transistor T14 are turned on. The signal of the second clock signal terminal CK2 is the high-level signal, the twenty-third transistor T23 is turned off. The turned-on seventeenth transistor T17 transmits the low-level signal of the input terminal SIN to the second node N2, and the signal of the second node N2 becomes a low-level signal, the turned-on twelfth transistor T12 transmits the low-level signal of the second node N2 to the third node N3, and the signal of the third node N3 becomes a low-level signal, the turned-on fourteenth transistor T14 transmits the low-level signal of the input terminal SIN to the eighth node N8, and the signal of the eighth node N8 becomes a low-level signal, the turned-on fifteenth transistor T15 transmits the low-level signal of the eighth node N8 to the twelfth node N12, the signal of the twelfth node N12 becomes a low-level signal, and the eighteenth transistor T18, the twentieth transistor T20, the twenty-fourth transistor T24, and the tenth transistor T10 are turned on. The turned-on eighteenth control transistor T18 transmits the low-level signal of the first clock signal terminal CK1 to the seventh node N7, a level of the seventh node N7 may be pulled down, so the seventh node N7 and the ninth node N9 continue to maintain a low level of the previous stage, and the twenty-first control transistor T21 and the twenty-second control transistor T22 are turned on. The signal of the second clock signal terminal CK2 is the high-level signal, the twenty-third transistor T23 is turned off. In addition, the turned-on twenty-fourth control transistor T24 transmits the high-level signal of the first power supply terminal V1 to the first node N1, and the ninth transistor T9 is turned off. The turned-on tenth transistor T10 outputs the low-level signal of the second power supply terminal V2, and the signal of the cascade output terminal SOUT turns to be at a low level.

An embodiment of the present disclosure further provides a gate driving circuit, including: a plurality of cascaded shift registers; a cascade output terminal of an i-th stage of shift register is electrically connected to a input terminal of an (i+1)-th stage of shift register, 1≤i≤M−1, and M is a total number of stages of the shift registers.

The shift register may be the shift register according to any one of the aforementioned embodiments, and its implementation principle and implementation effect are similar to the foresaid implementation principle and implementation effect and will not be repeated herein.

For different display products, cascade relationships of the plurality of shift registers in the gate driving circuit may be different. Regardless of the cascade relationships of the plurality of shift registers and no matter how many rows of sub-pixels are driven by each of the shift registers, as long as such a large-area device is changed and such a change creates additional space, both possible simple translation and stretching of a small device are within protection scope of the present disclosure.

A gate driving circuit according to an embodiment of the present disclosure is located in a display apparatus, wherein the display apparatus is further provided with a pixel circuit and a gate line, the pixel circuit is electrically connected to at least one gate line, and the scan output signal terminal of the shift register in the gate driving circuit is electrically connected to the gate line.

The gate driving circuit according to an embodiment of the present disclosure can drive the pixel circuit, to update the partial picture of the screen through the first control signal terminal MS1 to the third control signal terminal MS3, while the remaining picture does not need to be charged and discharged multiple times, thereby reducing the power consumption of the OLED display; or achieve ultra-low power consumption of OLED products such as wearables, mobile phones, and notebook computers (NB) through partial update of the display screen.

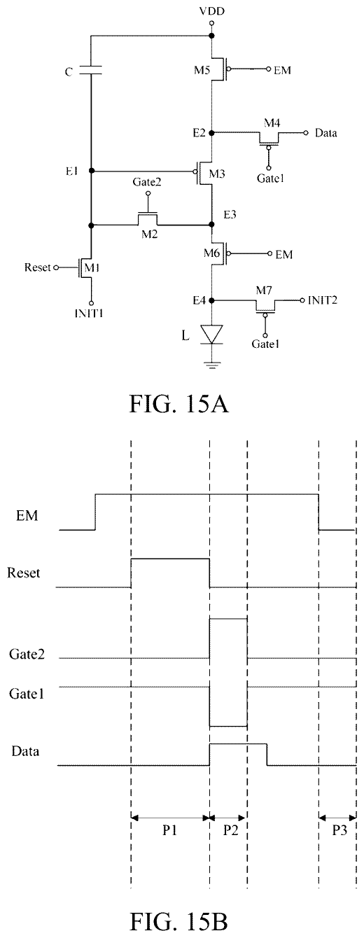

In an exemplary implementation mode, the pixel circuit may have a structure of 3T1C, 4T1C, 5T1C, 5T2C, 6T1C, 7T1C, or 8T1C. FIG. 15A is a schematic diagram of an equivalent circuit of a pixel circuit. As shown in FIG. 15A, the pixel circuit may include seven control transistors (a first control transistor M1 to a seventh control transistor M7), and one capacitor C.

As shown in FIG. 15A, a gate electrode of the first control transistor M1 is electrically connected to a reset signal line Reset, a first electrode of the first control transistor M1 is electrically connected to a first initial signal line INIT1, and a second electrode of the first control transistor M1 is electrically connected to a first node E1. A gate electrode of the second control transistor M2 is electrically connected to a second scan signal line Gate2, a first electrode of the second control transistor M2 is electrically connected to the first node E1, and a second electrode of the second control transistor M2 is electrically connected to a third node E3. A gate electrode of the third control transistor M3 is electrically connected to the first node E1, a first electrode of the third control transistor M3 is electrically connected to a second node E2, and a second electrode of the third control transistor M3 is electrically connected to the third node E3. A gate electrode of the fourth control transistor M4 is electrically connected to a first scan signal line Gate1, a first electrode of the fourth control transistor M4 is electrically connected to a data signal line Data, and a second electrode of the fourth control transistor M4 is electrically connected to the second node E2. A gate electrode of the fifth control transistor M5 is electrically connected to a light emitting signal line EM, a first electrode of the fifth control transistor M5 is electrically connected to a high-level power supply line VDD, and a second electrode of the fifth control transistor M5 is electrically connected to the second node E2. A gate electrode of the sixth control transistor M6 is electrically connected to the light emitting signal line EM, a first electrode of the sixth control transistor M6 is electrically connected to the third node E3, and a second electrode of the sixth control transistor M6 is electrically connected to a fourth node E4. A gate electrode of the seventh control transistor M7 is electrically connected to the first scan signal line Gate1, a first electrode of the seventh control transistor M7 is electrically connected to a second initial signal line INIT2, and a second electrode of the seventh control transistor M7 is electrically connected to the fourth node E4. A first plate of the capacitor C is electrically connected to the first node E1, and a second plate of the capacitor C is electrically connected to the high-level power supply line VDD.

In an exemplary implementation mode, for the first control transistor M1 to the seventh control transistor M7, low-temperature polysilicon thin-film control transistors may be used, or oxide thin-film control transistors may be used, or both a low-temperature polysilicon thin-film control transistor and an oxide thin-film control transistor may be used. An active layer of a low-temperature polysilicon thin-film control transistor is made of Low Temperature Poly Silicon (LTPS for short), and an active layer of an oxide thin-film control transistor is made of an oxide semiconductor (Oxide). The low-temperature polysilicon thin-film control transistor has advantages such as a high migration rate and fast charging, and the oxide thin-film control transistor has advantages such as a low leakage current. The low-temperature polysilicon thin-film control transistor and the oxide thin-film control transistor are integrated on one display substrate to form a LTPS+Oxide (LTPO) display substrate, and advantages of both the low-temperature polysilicon thin-film control transistor and the oxide thin-film control transistor may be utilized, which may achieve low frequency drive, reduce power consumption, and improve display quality.

In an exemplary implementation mode, a transistor type of the first control transistor M1 and the second control transistor M2 is opposite to that of the third control transistor M3 to the seventh control transistor M7. For example, the first control transistor M1 and the control second transistor M2 may be N-type control transistors, and the third control transistors M3 to the seventh control transistor M7 may be P-type control transistors.

In an exemplary implementation mode, the first control transistor M1 and the second control transistor M2 may be oxide control transistors, and the third control transistor M3 to the seventh control transistor M7 may be low-temperature polysilicon control transistors.

In an exemplary implementation mode, a voltage value of a signal of the first initial signal line INIT1 is constant and the signal is a Direct Current (DC) signal. The voltage value of the signal of the first initial signal line INIT1 may be −3V.

In an exemplary implementation mode, a voltage value of a signal of the second initial signal line INIT2 is constant and the signal is a DC signal, and the voltage value of the signal of the second initial signal line INIT2 may be OV.

In an exemplary implementation mode, the light emitting device L may be electrically connected to the fourth node E4 and a low-level power supply line VSS respectively.

In an exemplary implementation mode, the high-level power supply line VDD continuously provides a high-level signal, and the low power supply line VSS continuously provides a low-level signal.

FIG. 15B is a working timing diagram of the pixel circuit provided in FIG. 15A. An exemplary embodiment of the present disclosure is described below with reference to a working process of the pixel circuit illustrated in FIG. 15A during a display stage. FIG. 15B illustrates an exemplary embodiment in which a first control transistor M1 and a second control transistor M2 are N-type control transistors and a third control transistor M3 to a seventh control transistor M7 are P-type control transistors. A pixel circuit in FIG. 15B includes a first control transistor M1 to a seventh control transistors M7, one capacitor C, and eight signal lines (a data signal line Data, a first scan signal line Gate1, a second scan signal line Gate2, a reset signal line Reset, a first initial signal line INIT1, a second initial signal line INIT2, a light emitting signal line EM, and a high-level power supply line VDD).

With reference to FIGS. 15A and 15B, the working process of the pixel circuit may include following stages.

In a first stage P1, referred to as an initialization stage, a signal of the reset signal line Reset is a high-level signal, the first control transistor M1 is turned on, and a signal of the first initial signal line INIT1 is written to the first node E1 through the turned-on first control transistor M1, so as to initialize (reset) the first node E1, and empty a pre-stored voltage in the first node N1 to complete the initialization.

In a second stage P2, referred to as a data writing stage or a threshold compensation stage, a signal of the first scan signal line Gate1 is a low-level signal, a signal of the second scan signal line Gate2 is a low-level signal, and the data signal line Data outputs a data voltage. In this stage, since a signal of the first node E1 is a low-level signal, the third control transistor M3 is turned on. The signal of the first scan signal line Gate1 is the low-level signal, the fourth control transistor M4 and the seventh control transistor M7 are turned on, the signal of the second scan signal line Gate2 is the high-level signal, the second control transistor M2 is turned on, the data voltage output by the data signal line Data is provided to the first node E1 through the turned-on fourth control transistor M4, the second node E2, the turned-on third control transistor M3, the third node E3 and the turned-on second control transistor M2, a difference between the data voltage output by the data signal line Data and a threshold voltage of the third control transistor M3 is charged into the capacitor C until the voltage of the first node N1 is Vd−|Vth|, Vd is the data voltage output from the data signal line Data, Vth is the threshold voltage of the third control transistor M3, the seventh control transistor M7 is turned on, the signal of the second initial signal line INIT2 is written to the fourth node N4 through the turned-on seventh control transistor M7 to initialize (reset) a first electrode of the light emitting device L, and empty a pre-stored voltage in the first electrode of the light emitting device L to complete the initialization.

In a third stage P3, referred to as a light emitting stage, a signal of the light emitting signal line EM is a low-level signal, the fifth control transistor M5 and the sixth control transistor M6 are turned on, and a power supply voltage output by the high-level power supply line VDD provides a drive voltage to the first electrode of the light emitting device L through the turned-on fifth control transistor M5, the third control transistor M3, and the sixth control transistor M6, to drive the light emitting device L to emit light.

In the driving process of the pixel circuit, a drive current flowing through the third control transistor M3 (a drive control transistor) is determined by a voltage difference between a gate electrode and a first electrode of the third control transistor M3. Since the voltage of the first node E1 is Vd-|Vth|, the driving current of the third control transistor M3 is as follows:

I=K*(Vgs−Vth)²=K*[(Vdd−Vd+|Vth|)−Vth]²=K*(Vdd−Vd)²

Here, I is the driving current flowing through the third control transistor M3, that is, a driving current for driving the light emitting device L, K is a constant, Vgs is the voltage difference between the gate electrode and the first electrode of the third control transistor M3, Vth is the threshold voltage of the third control transistor M3, Vd is the data voltage output by the data signal line Data, and Vdd is the power supply voltage output by the high-level power supply line VDD.

In an exemplary embodiment, the gate driving circuit according to an embodiment of the present disclosure may be electrically connected to the second scan signal line Gate2.

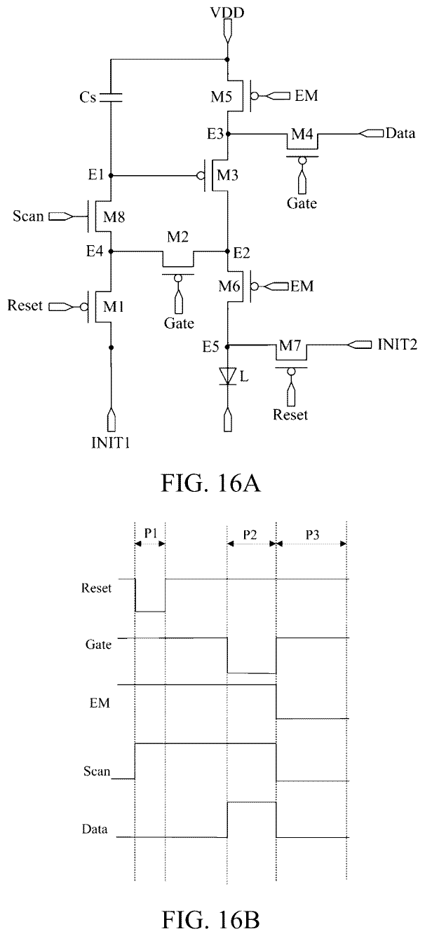

In an exemplary embodiment, FIG. 16A is an equivalent circuit diagram of another pixel circuit. As shown in FIG. 16A, the pixel circuit may include eight control transistors (a first control transistor M1 to an eighth control transistor M8), one capacitor C, and nine signal lines (a data signal line Data, a control signal line Scan, a scan signal line Gate, a reset signal line Reset, a light emitting signal line EM, a first initial signal line INIT1, a second initial signal line INIT2, a high-level power supply line VDD, and a low-level power supply line VSS).

In an exemplary implementation mode, as shown in FIG. 16A, a first plate of the capacitor C is connected to the high-level power supply line VDD and a second plate of the capacitor Cis connected to a first node E1. A control electrode of the first control transistor M1 is connected to the reset signal line Reset, a first electrode of the first control transistor M1 is connected to the first initial signal line INIT1, and a second electrode of the first control transistor is connected to a fourth node E4. A control electrode of the second control transistor M2 is connected to the scan signal line Gate, a first electrode of the second control transistor M2 is connected to the fourth node E4, and a second electrode of the second control transistor M2 is connected to a second node E2. A control electrode of the third control transistor M3 is connected to the first node E1, a first electrode of the third control transistor M3 is connected to a second node E2, and a second electrode of the third control transistor M3 is connected to a third node E3. A control electrode of the fourth control transistor M4 is connected to the scan signal line Gate, a first electrode of the fourth control transistor M4 is connected to the data signal line Data, and a second electrode of the fourth control transistor M4 is connected to the third node E3. A control electrode of the fifth control transistor M5 is connected to the light emitting signal line EM, a first electrode of the fifth control transistor M5 is connected to the high-level power supply line VDD, and a second electrode of the fifth control transistor M5 is connected to the third node E3. A control electrode of the sixth control transistor M6 is connected to the light emitting signal line EM, a first electrode of the sixth control transistor M6 is connected to the second node E2, and a second electrode of the sixth control transistor M6 is connected to a first electrode of a light emitting device L. A control electrode of the seventh control transistor M7 is connected to the reset signal line Reset, a first electrode of the seventh control transistor M7 is connected to the second initial signal line INIT2, a second electrode of the seventh control transistor M7 is connected to the first electrode of the light emitting device L, and a second electrode of the light emitting device L is connected to the low-level power supply line VSS. A control electrode of the eighth control transistor M8 is connected to the control signal line Scan, a first electrode of the eighth control transistor M8 is connected to the first node E1, and a second electrode of the eighth control transistor M8 is connected to the fourth node E4.

In an exemplary implementation mode, the control electrode of the seventh control transistor M7 may also be connected to the scan signal line Gate, the first electrode of the seventh control transistor M7 is connected to the second initial signal line INIT2, the second electrode of the seventh control transistor M7 is connected to the first electrode of the light emitting device L, and the second electrode of the light emitting device L is connected to the low-level power supply line VSS.

In an exemplary implementation mode, a signal of the high-level power supply line VDD is a high-level signal continuously provided, and a signal of the low-level power supply line VSS is a low-level signal.

In an exemplary implementation mode, the eighth control transistor M8 is a metal oxide control transistor, and is an N-type control transistor, and the first control transistor M1 to the seventh control transistor M7 are low-temperature polysilicon control transistors and are P-type control transistors.

In an exemplary embodiment, the eighth control transistor M8 is an oxide control transistor and may reduce a leakage current, improve performance of the pixel circuit, and may reduce power consumption of the pixel circuit.

In an exemplary embodiment, the gate driving circuit according to an embodiment of the present disclosure may be electrically connected to the control signal line Scan.

FIG. 16B is a working timing diagram of the pixel circuit provided in FIG. 16A. An exemplary embodiment of the present disclosure will be described below through a working process of the pixel circuit illustrated in FIG. 16B. The working process of the pixel circuit may include following stages.

In a first stage A1, referred to as a reset stage, signals of the control signal line Scan, the light emitting signal line EM, and the scan signal line Gate are all high-level signals, and a signal of the reset signal line Reset is a low-level signal. The signal of the reset signal line Reset is the low-level signal, the first control transistor M1 is turned on, a signal of the first initial signal line INIT1 is provided to the fourth node E4, the seventh control transistor M7 is turned on, an initial voltage of the second initial signal line INIT2 is provided to the first electrode of the light emitting device L to initialize (reset) the first electrode of the light emitting device L, for example, empty a pre-stored voltage therein, initialization is completed, and the light emitting device L is ensured not to emit light. A signal of the control signal line Scan is a high-level signal, the eighth control transistor M8 is turned on, a signal of the fourth node E4 is provided to the first node E1 to initialize the capacitor C, and an original data voltage in the capacitor C is cleared. Signals of the scan signal line Gate and the light emitting signal line EM are high-level signals, and the second control transistor M2, the fourth control transistor M4, the fifth control transistor M5, the sixth control transistor M6, and the seventh control transistor M7 are turned off, and the light emitting device L does not emit light in this stage.

In a second stage A2, referred to as a data writing stage or a threshold compensation stage, a signal of the scan signal line Gate is a low-level signal, signals of the reset signal line Reset, the light emitting signal line EM, and the control signal line Scan are high-level signals, and the data signal line Data outputs a data voltage. In this stage, since the first node E1 is a low-level signal, the third control transistor M3 is turned on. The signal of the scan signal line Gate is the low-level signal, the second control transistor M2 and the fourth control transistor M4 are turned on, the signal of the control signal line Scan is a high-level signal, and the eighth control transistor M8 is turned on. The second control transistor M2, the fourth control transistor M4, and the eighth control transistor M8 are turned on so that the data voltage output by the data signal line Data is provided to the first node E1 through the third node E3, the turned-on third control transistor M3, the second node E2, the turned-on second control transistor M2, the fourth node E4, and the turned-on eighth control transistor M8. A difference between the data voltage output by the data signal line Data and a threshold voltage of the third control transistor M3 is charged into the capacitor C until a voltage of the first node E1 is Vd−|Vth|, wherein Vd is the data voltage output by the data signal line Data, and Vth is the threshold voltage of the third control transistor M3. The signal of the reset signal line Reset is a low-level signal, and the first control transistor M1 and the seventh control transistor M7 are turned off. A signal of the light emitting signal line EM is a high-level signal, and the fifth control transistor M5 and the sixth control transistor M6 are turned off.

In a third stage A3, referred to as a light emitting stage, signals of the control signal line Scan and the light emitting signal line EM are both low-level signals, and signals of the scan signal line Gate and the reset signal line Reset are high-level signals. The signal of the reset signal line Reset is a low-level signal, and the first control transistor M1 and the seventh control transistor M7 are turned off. The signal of the control signal line Scan is a low-level signal, the signals of the scan signal line Gate and the reset signal line Reset are the high-level signals, and the second control transistor M2, the fourth control transistor M4, and the eighth control transistor M8 are turned off. The signal of the light emitting signal line EM is a low-level signal, the fifth control transistor M5 and the sixth control transistor M6 are turned on, and a power supply voltage output by the high-level power supply line VDD provides a drive voltage to the first electrode of the light emitting device L through the turned-on fifth control transistor M5, the third control transistor M3, and the sixth control transistor M6, so as to drive the light emitting device L to emit light.

In a driving process of the pixel circuit, a drive current flowing through the third control transistor M3 (drive control transistor) is determined by a voltage difference between a control electrode and a first electrode of the third transistor T3. Since the voltage of the first node E1 is Vd−|Vth|, the driving current of the third control transistor M3 is as follows:

$$I = K * {( Vgs - Vth )}^{2} = K * {[ ( Vdd - Vd + \vert Vth \vert ) - Vth ]}^{2} = K * {( Vdd - Vd )}^{2}$$

Herein, I is the driving current flowing through the third control transistor M3, i.e., a driving current for driving the light emitting device L, K is a constant, Vgs is the voltage difference between the control electrode and the first electrode of the third control transistor M3, Vth is the threshold voltage of the third control transistor M3, Vd is the data voltage output by the data signal line Data, and Vdd is the power voltage output by the high-level power supply line VDD.

The gate driving circuit according to an embodiment of the present disclosure can control the turn-on and turn-off of the gates of the transistors in the pixel circuit to refresh brightness of pixels. The gate driving circuit controls the gates of the transistors in the pixel circuit to be turned off, which can achieve that some pixels are not refreshed, and achieve that under some special pictures, such as AOD, still pictures or images with fewer updates, the voltages of related pixels are not updated, so as to avoid repeated writing of related pixels, which makes the display consume more power.

An embodiment of the present disclosure further provides a method for driving a shift register, which is configured to drive the shift register. The method for driving the shift register may include following operations:
providing, by the cascade output sub-circuit, a signal of the first power supply terminal or the second power supply terminal to the cascade output terminal under control of signals of the input terminal, the first clock signal terminal, the second clock signal terminal, the first node, the second node and the third node;
providing, by the output control sub-circuit, a signal of the first node to the fourth node and a signal of the second node to the fifth node under control of signals of the first node, the third node and the first control signal terminal to the third control signal terminal; and
outputting, by the scan output sub-circuit, a signal of the first power supply terminal or the second power supply terminal to the scan signal output terminal under control of signals of the fourth node and the fifth node.

The shift register is the shift register according to any one of the foregoing embodiments, and its implementation principle and implementation effects are similar to the foregoing implementation principle and implementation effects, and will not be repeated here.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although implementation modes of the present disclosure are disclosed above, contents described are only implementation modes used for ease of understanding of the present disclosure, but not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A shift register comprising: a cascade output sub-circuit, an output control sub-circuit, and a scan output sub-circuit;
the cascade output sub-circuit is electrically connected to an input terminal, a first clock signal terminal, a second clock signal terminal, a first power supply terminal, a second power supply terminal, a cascade output terminal, a first node, a second node, and a third node respectively, and is configured to provide a signal of the first power supply terminal or the second power supply terminal to the cascade output terminal under control of signals of the input terminal, the first clock signal terminal, the second clock signal terminal, the first node, the second node, and the third node;
the output control sub-circuit is electrically connected to a first control signal terminal, a second control signal terminal and a third control signal terminal, the first node, the second node, the third node, a fourth node, and a fifth node respectively, and is configured to provide a signal of the first node to the fourth node and to provide a signal of the second node to the fifth node under control of signals of the first node, the third node, and the first control signal terminal to the third control signal terminal; and
the scan output sub-circuit is electrically connected to the fourth node, the fifth node, a scan signal output terminal, the first power supply terminal, and the second power supply terminal, respectively, and is configured to output the signal of the first power supply terminal or the second power supply terminal to the scan signal output terminal under control of signals of the fourth node and the fifth node.

2. The shift register according to claim 1, wherein the output control sub-circuit comprises: a first control sub-circuit, a second control sub-circuit, and a third control sub-circuit;
the first control sub-circuit is electrically connected to the first node, the third node, a sixth node, the first control signal terminal, the second control signal terminal, and the third control signal terminal respectively, and is configured to provide a signal of the second control signal terminal or the third control signal terminal to the sixth node under control of the signals of the first node, the third node, and the first control signal terminal;
the second control sub-circuit is electrically connected to the first node, the fourth node, and the sixth node respectively, and is configured to provide the signal of the first node to the fourth node under control of a signal of the sixth node; and
the third control sub-circuit is electrically connected to the second node, the fifth node and the sixth node respectively, and is configured to provide the signal of the second node to the fifth node under control of the signal of the sixth node.

3. The shift register according to claim 2, wherein the first control sub-circuit comprises: a first transistor, a second transistor, a third transistor, and a fourth transistor;
a control electrode of the first transistor is electrically connected to the first control signal terminal, a first electrode of the first transistor is electrically connected to a second electrode of the second transistor, and a second electrode of the first transistor is electrically connected to the third control signal terminal;
a control electrode of the second transistor is electrically connected to the third node, and a first electrode of the second transistor is electrically connected to the sixth node;
a control electrode of the third transistor is electrically connected to the first control signal terminal, a first electrode of the third transistor is electrically connected to the second control signal terminal, and a second electrode of the third transistor is electrically connected to a first electrode of the fourth transistor; and
a control electrode of the fourth transistor is electrically connected to the first node, and a second electrode of the fourth transistor is electrically connected to the sixth node.

4. The shift register according to claim 2, wherein the second control sub-circuit comprises a fifth transistor;
a control electrode of the fifth transistor is electrically connected to the sixth node, a first electrode of the fifth transistor is electrically connected to the first node, and a second electrode of the fifth transistor is electrically connected to the fourth node.

5. The shift register according to claim 2, wherein the third control sub-circuit comprises a sixth transistor;
a control electrode of the sixth transistor is electrically connected to the sixth node, a first electrode of the sixth transistor is electrically connected to the second node, and a second electrode of the sixth transistor is electrically connected to the fifth node.

6. The shift register according to claim 2, wherein the output control sub-circuit further comprises: a storage sub-circuit;
the storage sub-circuit is electrically connected to the fourth node and the sixth node respectively, and is configured to store a voltage difference between signals of the sixth node and the fourth node.

7. The shift register according to claim 6, wherein the storage sub-circuit comprises a first capacitor comprising a first plate and a second plate;
the first plate of the first capacitor is electrically connected to the sixth node, and the second plate of the first capacitor is electrically connected to the fourth node.

8. The shift register according to claim 1, wherein the scan output sub-circuit comprises a seventh transistor, and an eighth transistor;
a control electrode of the seventh transistor is electrically connected to the fourth node, a first electrode of the seventh transistor is electrically connected to the first power supply terminal, and a second electrode of the seventh transistor is electrically connected to the scan signal output terminal; and
a control electrode of the eighth transistor is electrically connected to the fifth node, a first electrode of the eighth transistor is electrically connected to the scan signal output terminal, and a second electrode of the eighth transistor is electrically connected to the second power supply terminal.

9. The shift register according to claim 8, wherein the scan output sub-circuit further comprises: a second capacitor comprising a first plate and a second plate;
the first plate of the second capacitor is electrically connected to the fourth node, and the second plate of the second capacitor is electrically connected to the first power supply terminal.

10. The shift register according to claim 1, wherein the cascade output sub-circuit comprises: a ninth transistor to a twenty-fifth transistor, and a third capacitor to a sixth capacitor;
a control electrode of the ninth transistor is electrically connected to the first node, a first electrode of the ninth transistor is electrically connected to the first power supply terminal, and a second electrode of the ninth transistor is electrically connected to the cascade output terminal;
a control electrode of the tenth transistor is electrically connected to the third node, a first electrode of the tenth transistor is electrically connected to the second power supply terminal, and a second electrode of the tenth transistor is electrically connected to the cascade output terminal;
a control electrode of the eleventh transistor is electrically connected to the second power supply terminal, a first electrode of the eleventh transistor is electrically connected to a seventh node, and a second electrode of the eleventh transistor is electrically connected to a ninth node;
a control electrode of the twelfth transistor is electrically connected to the second power supply terminal, a first electrode of the twelfth transistor is electrically connected to the second node, and a second electrode of the twelfth transistor is electrically connected to the third node;
a control electrode of the thirteenth transistor is electrically connected to a third power supply terminal, a first electrode of the thirteenth transistor is electrically connected to the first power supply terminal, and a second electrode of the thirteenth transistor is electrically connected to the second node;
a control electrode of the fourteenth transistor is electrically connected to the first clock signal terminal, a first electrode of the fourteenth transistor is electrically connected to the input terminal, and a second electrode of the fourteenth transistor is electrically connected to an eighth node;
a control electrode of the fifteenth transistor is electrically connected to the second power supply terminal, a first electrode of the fifteenth transistor is electrically connected to the eighth node, and a second electrode of the fifteenth transistor is electrically connected to a twelfth node;
a control electrode of the sixteenth transistor is electrically connected to the twelfth node, a first electrode of the sixteenth transistor is electrically connected to the third node, and a second electrode of the sixteenth transistor is electrically connected to the twelfth node;
a control electrode of the seventeenth transistor is electrically connected to the first clock signal terminal, a first electrode of the seventeenth transistor is electrically connected to the input terminal, and a second electrode of the seventeenth transistor is electrically connected to the second node;
a control electrode of the eighteenth transistor is electrically connected to the second node, a first electrode of the eighteenth transistor is electrically connected to the first clock signal terminal, and a second electrode of the eighteenth transistor is electrically connected to the seventh node;
a control electrode of the nineteenth transistor is electrically connected to the first clock signal terminal, a first electrode of the nineteenth transistor is electrically connected to the second power supply terminal, and a second electrode of the nineteenth transistor is electrically connected to the seventh node;
a control electrode of the twentieth transistor is electrically connected to the second node, a first electrode of the twentieth transistor is electrically connected to the second clock signal terminal, and a second electrode of the twentieth transistor is electrically connected to an eleventh node;
a control electrode of the twenty-first transistor is electrically connected to the seventh node, a first electrode of the twenty-first transistor is electrically connected to the first power supply terminal, and a second electrode of the twenty-first transistor is electrically connected to the eleventh node;
a control electrode of the twenty-second transistor is electrically connected to the ninth node, a first electrode of the twenty-second transistor is electrically connected to the second clock signal terminal, and a second electrode of the twenty-second transistor is electrically connected to a tenth node;
a control electrode of the twenty-third transistor is electrically connected to the second clock signal terminal, a first electrode of the twenty-third transistor is electrically connected to the tenth node, and a second electrode of the twenty-third transistor is electrically connected to the first node;
a control electrode of the twenty-fourth transistor is electrically connected to the second node, a first electrode of the twenty-fourth transistor is electrically connected to the first power supply terminal, and a second electrode of the twenty-fourth transistor is electrically connected to the first node;
a control electrode of the twenty-fifth transistor is electrically connected to the twelfth node, a first electrode of the twenty-fifth transistor is electrically connected to the twelfth node, and a second electrode of the twenty-fifth transistor is electrically connected to the fifth node;
the third capacitor comprises a first plate and a second plate, the first plate of the third capacitor is electrically connected to the third node, and the second plate of the third capacitor is electrically connected to the eleventh node;
the fourth capacitor comprises a first plate and a second plate, the first plate of the fourth capacitor is electrically connected to the second power supply terminal, and the second plate of the fourth capacitor is electrically connected to the cascade output terminal;
the fifth capacitor comprises a first plate and a second plate, the first plate of the fifth capacitor is electrically connected to the ninth node, and the second plate of the fifth capacitor is electrically connected to the tenth node; and
the sixth capacitor comprises a first plate and a second plate, the first plate of the sixth capacitor is electrically connected to the first node, and the second plate of the sixth capacitor is electrically connected to the first power supply terminal.

11. The shift register according to claim 1, wherein the cascade output sub-circuit comprises: a ninth transistor to a twenty-fifth transistor, a third capacitor to a sixth capacitor, the output control sub-circuit comprises: a first transistor to a sixth transistor and a first capacitor, and the scan output sub-circuit comprises: a seventh transistor, an eighth transistor, and a second capacitor;
a control electrode of the first transistor is electrically connected to the first control signal terminal, a first electrode of the first transistor is electrically connected to a second electrode of the second transistor, and a second electrode of the first transistor is electrically connected to the third control signal terminal;
a control electrode of the second transistor is electrically connected to the third node, and a first electrode of the second transistor is electrically connected to a sixth node;
a control electrode of the third transistor is electrically connected to the first control signal terminal, a first electrode of the third transistor is electrically connected to the second control signal terminal, and a second electrode of the third transistor is electrically connected to a first electrode of the fourth transistor;
a control electrode of the fourth transistor is electrically connected to the first node, and a second electrode of the fourth transistor is electrically connected to the sixth node;
a control electrode of the fifth transistor is electrically connected to the sixth node, a first electrode of the fifth transistor is electrically connected to the first node, and a second electrode of the fifth transistor is electrically connected to the fourth node;
a control electrode of the sixth transistor is electrically connected to the sixth node, a first electrode of the sixth transistor is electrically connected to the second node, and a second electrode of the sixth transistor is electrically connected to the fifth node;
a control electrode of the seventh transistor is electrically connected to the fourth node, a first electrode of the seventh transistor is electrically connected to the first power supply terminal, and a second electrode of the seventh transistor is electrically connected to the scan signal output terminal;
a control electrode of the eighth transistor is electrically connected to the fifth node, a first electrode of the eighth transistor is electrically connected to the scan signal output terminal, and a second electrode of the eighth transistor is electrically connected to the second power supply terminal;
a control electrode of the ninth transistor is electrically connected to the first node, a first electrode of the ninth transistor is electrically connected to the first power supply terminal, and a second electrode of the ninth transistor is electrically connected to the cascade output terminal;
a control electrode of the tenth transistor is electrically connected to the third node, a first electrode of the tenth transistor is electrically connected to the second power supply terminal, and a second electrode of the tenth transistor is electrically connected to the cascade output terminal;
a control electrode of the eleventh transistor is electrically connected to the second power supply terminal, a first electrode of the eleventh transistor is electrically connected to a seventh node, and a second electrode of the eleventh transistor is electrically connected to a ninth node;
a control electrode of the twelfth transistor is electrically connected to the second power supply terminal, a first electrode of the twelfth transistor is electrically connected to the second node, and a second electrode of the twelfth transistor is electrically connected to the third node;
a control electrode of the thirteenth transistor is electrically connected to a third power supply terminal, a first electrode of the thirteenth transistor is electrically connected to the first power supply terminal, and a second electrode of the thirteenth transistor is electrically connected to the second node;
a control electrode of the fourteenth transistor is electrically connected to the first clock signal terminal, a first electrode of the fourteenth transistor is electrically connected to the input terminal, and a second electrode of the fourteenth transistor is electrically connected to an eighth node;
a control electrode of the fifteenth transistor is electrically connected to the second power supply terminal, a first electrode of the fifteenth transistor is electrically connected to the eighth node, and a second electrode of the fifteenth transistor is electrically connected to a twelfth node;
a control electrode of the sixteenth transistor is electrically connected to the twelfth node, a first electrode of the sixteenth transistor is electrically connected to the third node, and a second electrode of the sixteenth transistor is electrically connected to the twelfth node;
a control electrode of the seventeenth transistor is electrically connected to the first clock signal terminal, a first electrode of the seventeenth transistor is electrically connected to the input terminal, and a second electrode of the seventeenth transistor is electrically connected to the second node;
a control electrode of the eighteenth transistor is electrically connected to the second node, a first electrode of the eighteenth transistor is electrically connected to the first clock signal terminal, and a second electrode of the eighteenth transistor is electrically connected to the seventh node;
a control electrode of the nineteenth transistor is electrically connected to the first clock signal terminal, a first electrode of the nineteenth transistor is electrically connected to the second power supply terminal, and a second electrode of the nineteenth transistor is electrically connected to the seventh node;
a control electrode of the twentieth transistor is electrically connected to the second node, a first electrode of the twentieth transistor is electrically connected to the second clock signal terminal, and a second electrode of the twentieth transistor is electrically connected to an eleventh node;
a control electrode of the twenty-first transistor is electrically connected to the seventh node, a first electrode of the twenty-first transistor is electrically connected to the first power supply terminal, and a second electrode of the twenty-first transistor is electrically connected to the eleventh node;
a control electrode of the twenty-second transistor is electrically connected to the ninth node, a first electrode of the twenty-second transistor is electrically connected to the second clock signal terminal, and a second electrode of the twenty-second transistor is electrically connected to a tenth node;
a control electrode of the twenty-third transistor is electrically connected to the second clock signal terminal, a first electrode of the twenty-third transistor is electrically connected to the tenth node, and a second electrode of the twenty-third transistor is electrically connected to the first node;
a control electrode of the twenty-fourth transistor is electrically connected to the second node, a first electrode of the twenty-fourth transistor is electrically connected to the first power supply terminal, and a second electrode of the twenty-fourth transistor is electrically connected to the first node;
a control electrode of the twenty-fifth transistor is electrically connected to the twelfth node, a first electrode of the twenty-fifth transistor is electrically connected to the twelfth node, and a second electrode of the twenty-fifth transistor is electrically connected to the fifth node;
the first capacitor comprises a first plate and a second plate, the first plate of the first capacitor is electrically connected to the sixth node, and the second plate of the first capacitor is electrically connected to the fourth node;
the second capacitor comprises a first plate and a second plate, the first plate of the second capacitor is electrically connected to the fourth node, and the second plate of the second capacitor is electrically connected to the first power supply terminal;
the third capacitor comprises a first plate and a second plate, the first plate of the third capacitor is electrically connected to the third node, and the second plate of the third capacitor is electrically connected to the eleventh node;
the fourth capacitor comprises a first plate and a second plate, the first plate of the fourth capacitor is electrically connected to the second power supply terminal, and the second plate of the fourth capacitor is electrically connected to the cascade output terminal;
the fifth capacitor comprises a first plate and a second plate, the first plate of the fifth capacitor is electrically connected to the ninth node, and the second plate of the fifth capacitor is electrically connected to the tenth node; and
the sixth capacitor comprises a first plate and a second plate, the first plate of the sixth capacitor is electrically connected to the first node, and the second plate of the sixth capacitor is electrically connected to the first power supply terminal.

12. The shift register according to claim 1, wherein the shift register is disposed on a display substrate comprising: a plurality of scan signal lines, a working process of the display substrate comprises: display stages and blank stages between display stages; the display substrate comprises: a plurality of display regions, and refresh frequencies of different display regions comprise a first refresh frequency and a second refresh frequency, and the first refresh frequency is greater than the second refresh frequency;
in a state in which the working process of the display substrate is in a blank stage, when a signal of the first control signal terminal is a low-level signal, signals of the second control signal terminal and the third control signal terminal are low-level signals;
in a state in which the working process of the display substrate is in a display stage and the shift register is connected to a scan signal line located in a display region at the first refresh frequency, when the signal of the first control signal terminal is a low-level signal, signals of the second control signal terminal and the third control signal terminal are low-level signals;
in a state in which the working process of the display substrate is in a display stage, the shift register is connected to a scan signal line located in a display region at the second refresh frequency, and the cascade output terminal of the shift register outputs a low-level signal, when the signal of the first control signal terminal is a low-level signal, a signal of the second control signal terminal is a high-level signal, and a signal of the third control signal terminal is a low-level signal;
in a state in which the working process of the display substrate is in a display stage, the shift register is connected to a scan signal line located in a display region at the second refresh frequency, and the cascade output terminal of the shift register outputs a high-level signal, when the signal of the first control signal terminal is a low-level signal, the signal of the second control signal terminal is a high-level signal, and the signal of the third control signal terminal is a low-level signal;
in a state in which the working process of the display substrate is in a display stage, the shift register is connected to a scan signal line located in a display region at the second refresh frequency, and the cascade output terminal of the shift register outputs a low-level signal, when the signal of the first control signal terminal is a low-level signal, the signal of the second control signal terminal is a high-level signal, and the signal of the third control signal terminal is a low-level signal; and
a duration during which the signal of the first control signal terminal is a low-level signal is less than a duration during which either of the signal of the second control signal terminal and the signal of the third control signal terminal is a low-level signal.

13. A gate driving circuit, comprising a plurality of cascaded shift registers according to claim 1;
a cascade output terminal of an i-th stage of shift register is electrically connected to a input terminal of an (i+1)-th stage of shift register, 1≤i≤M−1, and M is a total number of stages of the shift registers.

14. A method for driving a shift register, configured to drive the shift register according to claim 1, wherein the method comprises:
providing, by the cascade output sub-circuit, a signal of the first power supply terminal or the second power supply terminal to the cascade output terminal under control of signals of the input terminal, the first clock signal terminal, the second clock signal terminal, the first node, the second node and the third node;
providing, by the output control sub-circuit, a signal of the first node to the fourth node and a signal of the second node to the fifth node under control of signals of the first node, the third node and the first control signal terminal to the third control signal terminal; and
outputting, by the scan output sub-circuit, a signal of the first power supply terminal or the second power supply terminal to the scan signal output terminal under control of signals of the fourth node and the fifth node.
